(19) United States
(12) Patent Application Publication
(10) Pub. No.: US 2026/0107589 A1
(43) Pub. Date: Apr. 16, 2026

(54) IMAGE SENSOR

(71) Applicant: Samsung Electronics Co., Ltd., Suwon-si (KR)

(72) Inventors: Masato FUJITA, Suwon-si (KR); Yunhyeok KIM, Suwon-si (KR); Kyungduck LEE, Suwon-si (KR); Seungki JUNG, Suwon-si (KR)

(73) Assignee: Samsung Electronics Co., Ltd., Suwon-si (KR)

(21) Appl. No.: 19/308,459

(22) Filed: Aug. 25, 2025

(30) Foreign Application Priority Data
Oct. 14, 2024 (KR) 10-2024-0139145

(51) Int. Cl. H10F 39/00

(52) U.S. Cl. CPC H10F 39/802; H10F 39/811

(57) ABSTRACT

Disclosed is an image sensor comprising a substrate including first and second light-receiving sections spaced apart from each other, a first transfer gate electrode on the first light-receiving section, a first floating diffusion region in the substrate on a side of the first transfer gate electrode, a first source follower gate electrode on the second light-receiving section, a first connection pattern connected to the first floating diffusion region, a second connection pattern connecting the first connection pattern to the first source follower gate electrode, a first interlayer dielectric layer covering the components on the substrate, and a first interconnection line on the first interlayer dielectric layer and connected to the first transfer gate electrode. A top end of the second connection pattern is at a first level. A bottom end of the first interconnection line is at a second level higher than the first level.

### CROSS-REFERENCE TO RELATED APPLICATION

This application claims priority under 35 U.S. C § 119 and benefit to Korean Patent Application No. 10-2024-0139145 filed on Oct. 14, 2024 in the Korean Intellectual Property Office, the disclosure of which is hereby incorporated by reference in its entirety.

### BACKGROUND

The present inventive concepts relate to image sensors.

An image sensor is a semiconductor device to transforms optical images into electrical signals. The image sensor may be classified into a charge coupled device (CCD) type and a complementary metal oxide semiconductor (CMOS) type. The CIS (CMOS image sensor) is a short for the CMOS type image sensor. The CIS may include a plurality of two-dimensionally arranged pixels. Each of the pixels includes a photodiode (PD). The photodiode serves to transform an incident light into an electrical signal.

### SUMMARY

In some example embodiments of the present inventive concepts an image sensor capable of accomplishing sharp image quality may be provided.

According to some example embodiments of the present inventive concepts, an image sensor may comprise: a substrate including a first light-receiving section and a second light-receiving section that are spaced apart from each other; a first transfer gate electrode on the first light-receiving section; a first floating diffusion region in the substrate, the first floating diffusion region on a side of the first transfer gate electrode; a first source follower gate electrode on the second light-receiving section; a first connection pattern connected to the first floating diffusion region; a second connection pattern connecting the first connection pattern to the first source follower gate electrode; a first interlayer dielectric layer covering the substrate, the first transfer gate electrode, the first source follower gate electrode, the first connection pattern, and the second connection pattern; and a first interconnection line on the first interlayer dielectric layer, the first interconnection line connected to the first transfer gate electrode. A top end of the second connection pattern may be at a first level. A bottom end of the first interconnection line may be at a second level higher than the first level.

According to some example embodiments of the present inventive concepts, an image sensor may comprise: a substrate including a first light-receiving section and a second light-receiving section that are spaced apart from each other; a first transfer gate electrode on the first light-receiving section; a first floating diffusion region in the substrate on a side of the first transfer gate electrode; a dual conversion gain gate electrode on the second light-receiving section; a second floating diffusion region in the substrate on a side of the dual conversion gain gate electrode; a first connection pattern connected to the first floating diffusion region; and a second connection pattern connecting the first connection pattern to the second floating diffusion region. The first floating diffusion region and the first connection pattern may be doped with a first impurity of a first conductivity type. A concentration of the first impurity in the first connection pattern may be greater than a concentration of the first impurity in the first floating diffusion region.

According to some example embodiments of the present inventive concepts, an image sensor may comprise: a substrate including first, second, third, and fourth light-receiving sections that are arranged in a clockwise direction, each of the first to fourth light-receiving sections includes a left sub-section and a right sub-section, and the substrate has a first surface and a second surface that are opposite to each other; a plurality of transfer gate electrodes on the left sub-sections and the right sub-sections of the first to fourth light-receiving sections; a plurality of first floating diffusion regions on sides of the transfer gate electrodes and on the left sub-sections and the right sub-sections; a source follower gate electrode on the fourth light-receiving section; a second floating diffusion region on the left sub-section of the third light-receiving section; a first connection pattern in contact with the first floating diffusion regions on the first and fourth light-receiving sections; a second connection pattern in contact with the first floating diffusion regions on the second and third light-receiving sections; a third connection pattern on the first surface, the third connection pattern connecting the first connection pattern, the second connection pattern, the source follower gate electrode, and the second floating diffusion region; a color filter on the second surface; and a microlens on the color filter. The transfer gate electrode may include a protruding part extending into the substrate. On the first light-receiving section, a first distance between the first connection pattern and the protruding part of the transfer gate electrode may be greater than a second distance between the first floating diffusion region and the protruding part of the transfer gate electrode.

According to some example embodiments of the present inventive concepts, a method of manufacturing an image sensor may include forming a substrate, the substrate including a photoelectric conversion region, a source follower gate electrode, and a separation element between the photoelectric conversion region and the source follower gate electrode; forming a first connection pattern in contact with the photoelectric conversion region and the separation element; forming a mask pattern on the photoelectric conversion region, the source follower gate electrode, and the first connection patter, the mask pattern exposing an upper surface of the first connection pattern, and upper surface of the separation element, and an upper surface of the source follower gate electrode; forming a second connection pattern on the upper surfaces of the photoelectric conversion region, the source follower gate electrode, and the first connection pattern exposed by the mask pattern, the second connection pattern connecting the first connection pattern and the source follower gate electrode; and covering the second connection pattern with a dielectric material, the dielectric material and the mask pattern forming a dielectric layer on the photoelectric conversion region, the source follower gate electrode, the separation element, the first connection pattern, and the second connection pattern.

According to some example embodiments of the present inventive concepts, a method of manufacturing an image sensor may include wherein the upper surface of the first connection pattern is coplanar with the upper surface of the connection pattern.

According to some example embodiments of the present inventive concepts, a method of manufacturing an image sensor may include wherein the upper surface of the source follower gate electrode is coplanar with the upper surface of the first connection pattern.

According to some example embodiments of the present inventive concepts, a method of manufacturing an image sensor may include wherein the upper surface of the first connection pattern, the upper surface of the source follower gate electrode, and the upper surface of the separation element are coplanar.

According to some example embodiments of the present inventive concepts, a method of manufacturing an image sensor may include wherein an upper surface of the second connection pattern is between the upper surface of the source follower gate electrode and an upper surface of the dielectric layer.

According to some example embodiments of the present inventive concepts, a method of manufacturing an image sensor may include wherein the upper surface of the first connection pattern is between the upper surface of the second connection pattern and the upper surface of the separation element.

According to some example embodiments of the present inventive concepts, a method of manufacturing an image sensor may include wherein the substrate further includes a transfer gate electrode, the transfer gate electrode includes a first portion on an upper surface of the substrate and a second portion extending into the substrate, and the photoelectric conversion region and the second portion of the transfer gate electrode are spaced apart by a first distance in a horizontal direction.

According to some example embodiments of the present inventive concepts, a method of manufacturing an image sensor may include wherein the first connection pattern is spaced apart from the second portion of the transfer gate electrode by a second distance in the horizontal direction, and the second distance is greater than the first distance.

According to some example embodiments of the present inventive concepts, a method of manufacturing an image sensor may include wherein the second connection pattern is spaced apart from the second portion of the transfer gate electrode by a third distance in the horizontal direction, and the third distance is greater than the second distance.

According to some example embodiments of the present inventive concepts, a method of manufacturing an image sensor may include wherein the source follower gate electrode includes at least one protruding portion extending into the substrate.

According to some example embodiments of the present inventive concepts, a method of manufacturing an image sensor may include wherein the second connection pattern includes titanium, titanium nitride, tantalum, tantalum nitride, or any combination thereof.

### BRIEF DESCRIPTION OF DRAWINGS

FIG. 1 illustrates a layout showing an image sensor according to some example embodiments of the present inventive concepts.

FIG. 2 illustrates a cross-sectional view taken along line A-A′ of FIG. 1 according to some example embodiments of the present inventive concepts.

FIG. 3 illustrates a cross-sectional view taken along line B-B′ of FIG. 1 according to some example embodiments of the present inventive concepts.

FIG. 4 illustrates a cross-sectional view taken along line C-C′ of FIG. 1 according to some example embodiments of the present inventive concepts.

FIG. 5 illustrates a cross-sectional view taken along line D-D′ of FIG. 1 according to some example embodiments of the present inventive concepts.

FIG. 6 illustrates a circuit diagram showing an image sensor of FIG. 1 according to some example embodiments of the present inventive concepts.

FIGS. 7A to 7E illustrate cross-sectional views showing a method of fabricating an image sensor having the cross-section of FIG. 4.

FIG. 8 illustrates a layout showing an image sensor according to some example embodiments of the present inventive concepts.

FIG. 9 illustrates a cross-sectional view taken along line C-C′ of FIG. 8 according to some example embodiments of the present inventive concepts.

FIG. 10 illustrates a cross-sectional view taken along line D-D′ of FIG. 8 according to some example embodiments of the present inventive concepts.

FIG. 11 illustrates a layout showing an image sensor according to some example embodiments of the present inventive concepts.

FIG. 12 illustrates a cross-sectional view taken along line C-C′ of FIG. 11 according to some example embodiments of the present inventive concepts.

FIG. 13 illustrates a cross-sectional view taken along line D-D′ of FIG. 11 according to some example embodiments of the present inventive concepts.

FIG. 14 illustrates a plan view showing an image sensor according to some example embodiments of the present inventive concepts.

FIG. 15 illustrates a cross-sectional view taken along line C-C′ of FIG. 14 according to some example embodiments of the present inventive concepts.

FIG. 16 illustrates a cross-sectional view taken along line C-C′ of FIG. 14 according to some example embodiments of the present inventive concepts.

FIG. 17 illustrates a cross-sectional view taken along line C-C′ of FIG. 14 according to some example embodiments of the present inventive concepts.

FIG. 18 illustrates a layout showing an image sensor according to some example embodiments of the present inventive concepts.

FIG. 19 illustrates a layout showing an image sensor according to some example embodiments of the present inventive concepts.

FIG. 20 illustrates a layout showing an image sensor according to some example embodiments of the present inventive concepts.

FIG. 21 illustrates a layout showing an image sensor according to some example embodiments of the present inventive concepts.

FIG. 22 illustrates a layout showing an image sensor according to some example embodiments of the present inventive concepts.

FIG. 23 illustrates a layout showing an image sensor according to some example embodiments of the present inventive concepts.

FIG. 24 illustrates a layout showing an image sensor according to some example embodiments of the present inventive concepts.

FIG. 25 illustrates a layout showing an image sensor according to some example embodiments of the present inventive concepts.

FIG. 26 illustrates a layout showing an image sensor according to some example embodiments of the present inventive concepts.

FIG. 27 illustrates a cross-sectional view showing an image sensor according to some example embodiments of the present inventive concepts.

FIGS. 28A to 28D illustrate cross-sectional views showing a method of fabricating an image sensor having the cross-section of FIG. 27.

### DETAILED DESCRIPTION

Some embodiments of the present inventive concepts will now be described in detail with reference to the accompanying drawings to aid in clearly explaining the present inventive concepts. In this description, such terms as “first” and “second” may be used to simply distinguish identical or similar components from each other, and the sequence of such terms may be changed in accordance with the order of mention. The term “first impurity” may be called “first dopant,” and the term “second impurity” may be called “second dopant.”

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

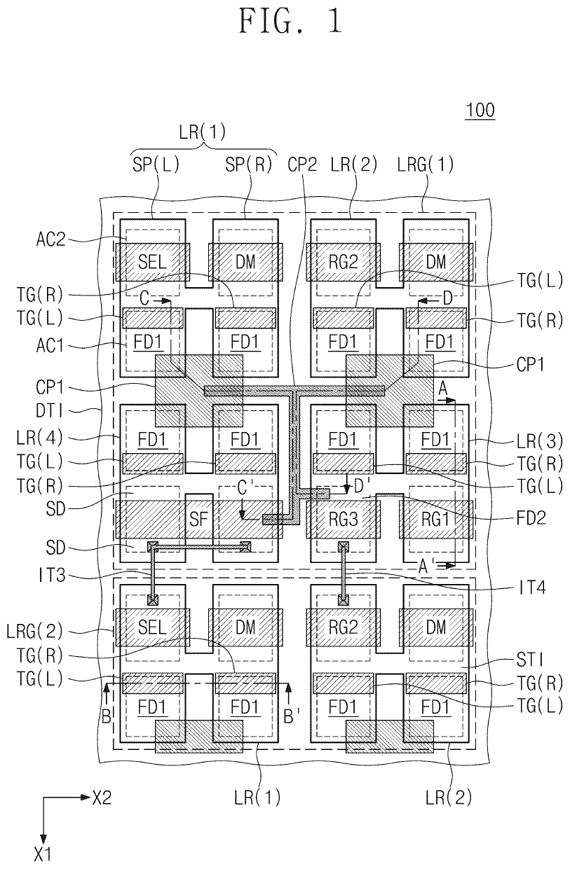

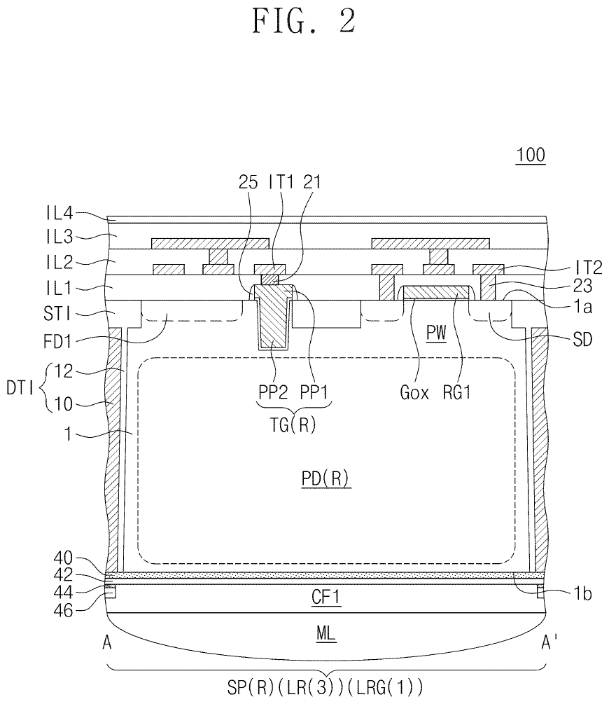

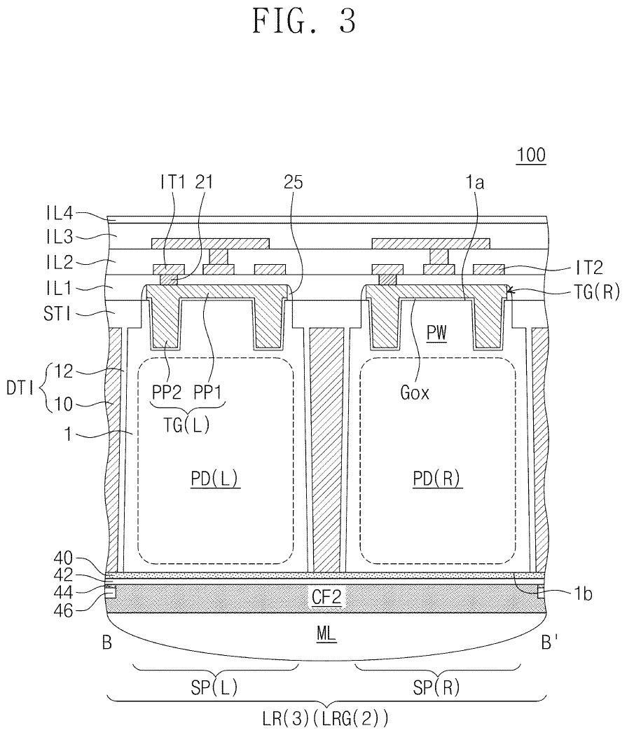

FIG. 1 illustrates a layout showing an image sensor according to some example embodiments of the present inventive concepts. FIG. 2 illustrates a cross-sectional view taken along line A-A′ of FIG. 1 according to some example embodiments of the present inventive concepts. FIG. 3 illustrates a cross-sectional view taken along line B-B′ of FIG. 1 according to some example embodiments of the present inventive concepts.

Referring to FIGS. 1 to 3, a substrate 1 may be provided to an image sensor 100 according to the present inventive concepts. The image sensor may have both an automatic focus function and an image sensor function. The substrate 1 may have a first surface 1a and a second surface 1b that are opposite to each other. The substrate 1 may receive light through the second surface 1b. The substrate 1 may be either a monocrystalline wafer including silicon and/or germanium or a silicon-on-insulator (SOI) substrate. A well region PW may be formed in an entirety of the substrate 1. The well region PW may be doped with a first impurity having a first conductivity type. The first conductivity type may be, for example, p-type. The first impurity may be, for example, boron.

The substrate 1 may be provided therein with a first separation part DTI that divide and limits light-receiving sections LR. The first separation part DTI may have a mesh shape when viewed in plan. The first separation part DTI may penetrate the substrate 1 to isolate each of the light-receiving sections LR.

The first separation part DTI may include a separation conductive pattern 10 and a separation dielectric pattern 12. The separation conductive pattern 10 may be spaced apart from the substrate 1. The separation conductive pattern 10 may include a conductive material having a refractive index different from that of the substrate 1. The separation conductive pattern 10 may include, for example, metal or polysilicon doped with impurities. A negative bias voltage may be applied to the separation conductive pattern 10. The separation conductive pattern 10 may serve as a common bias line. Therefore, holes possibly present on a surface of the substrate 1 in contact with the first separation part DTI may be trapped to improve dark current properties.

The separation dielectric pattern 12 may be interposed between the separation conductive pattern 10 and the substrate 1. The separation dielectric pattern 12 may include a dielectric material having a refractive index different from that of the substrate 1. For example, the separation dielectric pattern 12 may include silicon oxide.

The light-receiving sections LR may be two-dimensionally arranged along a first direction X1 and a second direction X2. The light-receiving sections LR may include first to fourth light-receiving sections LR(1) to LR(4) that are disposed along a clockwise direction. The first to fourth light-receiving sections LR(1) to LR(4) that are adjacent to each other may constitute on group section LRG. The group section LRG may be provided in plural, and the plurality of group sections LRG may be two-dimensionally arranged along the first direction X1 and the second direction X2. For example, the group section LRG may include a first group section LRG(1) and a second group section LRG(2) that are arranged side by side along the first direction X1.

A single group section LRG may be divided into a left sub-section SP(L) and a right sub-section SP(R). The left sub-section SP(L) and the right sub-section SP(R) may be disposed side by side in the second direction X2. The second direction X2 may be parallel to the first surface 1a. A portion of the first separation part DTI may be inserted into between the left sub-section SP(L) and the right sub-section SP(R). A cutting region may be provided between the left sub-section SP(L) and the right sub-section SP(R). On the cutting region, the first separation part DTI may be cut to disappear. For example, each of the first to fourth light-receiving sections LR(1) to LR(4) that constitute a group section LRG may each include a left sub-section SP(L) and a right sub-section SP(R).

The first separation part DTI may separate one light-receiving section LR from a neighboring light-receiving section LR. On one light-receiving section LR, the left sub-section SP(L) and the right sub-section SP(R) may be connected to each other through the well region PW.

The substrate 1 may be provided therein with a second separation part STI adjacent to the first surface 1a. A shallow trench isolation (STI) method may be used to form the second separation part STI. The second separation part STI may be formed to have a single or multiple structure of at least one selected from a silicon oxide layer, a silicon nitride layer, and/or a silicon oxynitride layer. When the separation dielectric pattern 12 of the first separation part DTI and the second separation part STI are formed of the same dielectric material, an interface may not be found therebetween the separation dielectric pattern 12 and the second separation part STI.

Alternatively, the second separation part STI may be an impurity doped region. In this case, the second separation part STI may be doped with the first impurity of the first conductivity type the same as that doped in the well region PW, and a doping concentration of the first impurity in the second separation part STI may be greater than that of the first impurity in the well region PW.

The second separation part STI may limit active regions AC1 and AC2 on the first surface 1a. On each of the left sub-section SP(L) and the right sub-section SP(R), first and second active regions AC1 and AC2 may be disposed side by side along a direction opposite to the first direction X1. In some example embodiments, each left sub-section SP(L) may include first and second active regions AC1 and AC2 spaced apart in the first direction X1. In some example embodiments, each right sub-section SP(R) may include first and second active regions AC1 and AC2 spaced apart in the first direction X1. In some example embodiments, the left-subsection SP(L) and the right sub-section SP(R) are spaced apart in the second direction X2 such that the first and second active regions AC1 and AC2 on the left-subsection SP(L) and the right sub-section SP(R) are spaced apart in the second direction X2. In some example embodiments, first active region AC1 on the right sub-section SP(R) and the first active region on the left sub-section SP(L) may be aligned in the second direction X2.

A transfer gate electrode TG may be disposed on the first active region AC1. A first floating diffusion region FD1 may be disposed in the substrate 1 on a side of the transfer gate electrode TG. A left transfer gate electrode TG(L) may be disposed on the first active region AC1 of the left sub-section SP(L). A right transfer gate electrode TG(R) may be disposed on the first active region AC1 of the right sub-section SP(R). The first floating diffusion region FD1 may be doped with a second impurity having a second conductivity type opposite to the first conductivity type. For example, the second conductivity type may be n-type, and the second impurity may be phosphorus or arsenic.

The transfer gate electrode TG may include a primary part PP1 disposed on the first surface 1a of the substrate 1 and protruding parts PP2 inserted into the substrate 1. According to some example embodiments, the number of the protruding parts PP2 in the transfer gate electrode TG may be two, but the present inventive concepts are not limited thereto. The number of the protruding parts PP2 may be either one or three or more. In some example embodiments, the transfer gate electrode TG may be a planar type electrode in which the protruding parts PP2 are not included. A gate dielectric layer Gox may be interposed between the transfer gate electrode TG and the substrate 1. The gate dielectric layer Gox may include a single or multiple layers of at least one selected from silicon oxide, metal oxide, silicon nitride, and silicon oxynitride.

The second active region AC2 may be provided thereon with one gate electrode among first, second, and third reset gate electrodes RG1, RG2, and RG3, a source follower gate electrode SFG, a dummy gate electrode DM, and a selection gate electrode SEL. Each of the gate electrodes RG1, RG2, RG3, SFG, SEL, and DM may be a planar type electrode as shown in FIG. 2. Alternatively, a portion of at least one selected from RG1, RG2, RG3, SFG, SEL, and DM may be inserted into the substrate 1.

Source/drain regions SD may be disposed on opposite sides of each of the gate electrodes RG1, RG2, RG3, SFG, SEL, and DM. The source/drain regions SD may be doped with the second impurity of the second conductivity type opposite to the first conductivity type. For example, the second conductivity type may be n-type, and the second impurity may be phosphorus or arsenic.

The selection gate electrode SEL may be disposed on the second active region AC2 of the left sub-section SP(L) in the first light-receiving section LR(1). The dummy gate electrode DM may be disposed on the second active region AC2 of the right sub-section SP(R) in the first light-receiving section LR(1).

The second reset gate electrode RG2 may be disposed on the second active region AC2 of the left sub-section SP(L) in the second light-receiving section LR(2). The dummy gate electrode DM may be disposed on the second active region AC2 of the right sub-section SP(R) in the second light-receiving section LR(2).

The third reset gate electrode RG3 may be disposed on the second active region AC2 of the left sub-section SP(L) in the third light-receiving section LR(3). A second floating diffusion region FD2 may be defined to refer to the source/drain region SD on a side of the third reset gate electrode RG3. The second floating diffusion region FD2 may be doped with the second impurity of the second conductivity type. A concentration of the second impurity doped in the second floating diffusion region FD2 may be greater than that of the second impurity doped in the first floating diffusion region FD1. The first reset gate electrode RG1 may be disposed on the second active region AC2 of the right sub-section SP(R) in the third light-receiving section LR(3).

The source follower gate electrode SFG may be disposed on the second active region AC2 of the left sub-section SP(L) in the fourth light-receiving section LR(4). The source follower gate electrode SFG may extend onto the second active region AC2 of the right sub-section SP(R) in the fourth light-receiving section LR(4).

The transfer gate electrode TG and the gate electrodes RG1, RG2, RG3, SFG, SEL, and DM may each be formed of a conductive material, for example, impurity-doped polysilicon. The transfer gate electrode TG and the gate electrodes RG1, RG2, RG3, SFG, SEL, and DM may each further include metal. A spacer 25 may cover sidewalls of the transfer gate electrode TG and the gate electrodes RG1, RG2, RG3, SFG, SEL, and DM. The spacer 25 may include a dielectric material, such as silicon oxide and silicon nitride. Each of the second and third reset gate electrodes RG2 and RG3 may be called “dual conversion gain gate electrode.”

Two photoelectric conversion regions PD may be disposed in one light-receiving section LR. On the left sub-section SP(L), a left photoelectric conversion region PD(L) may be disposed in the substrate 1. On the right sub-section SP(R), a right photoelectric conversion region PD(R) may be disposed in the substrate 1. The left photoelectric conversion region PD(L) and the right photoelectric conversion region PD(R) may be doped with the second impurity of the second conductivity type opposite to the first conductivity type of the first impurity. The second conductivity type may be n-type, and the second impurity may be phosphorus or arsenic. An n-type impurity region of each of the left and right photoelectric conversion regions PD(L) and PD(R) and a p-type impurity region of the well region PW therearound may form a PN junction, thereby constituting a photodiode. When light is incident, the PN junction may generate electron-hole pairs.

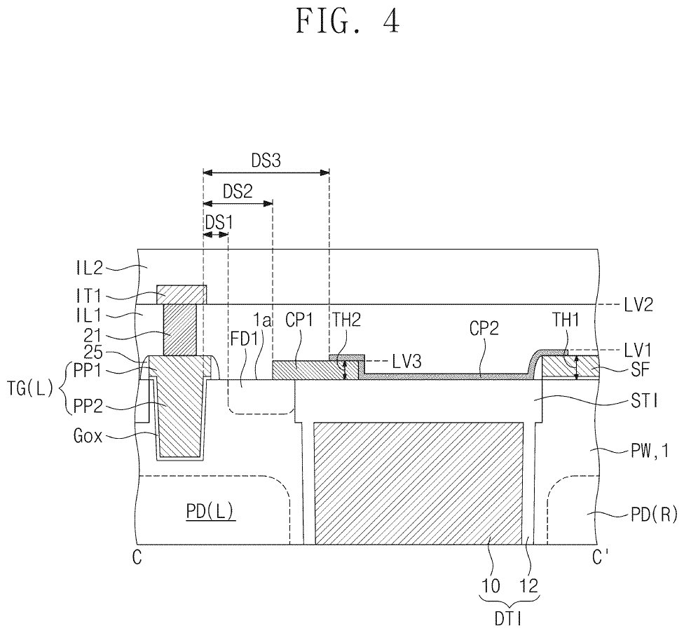

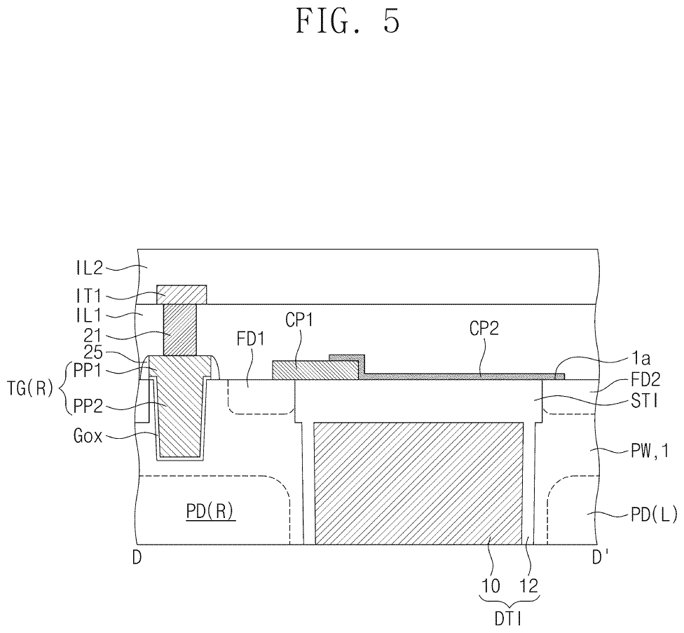

FIG. 4 illustrates a cross-sectional view taken along line C-C′ of FIG. 1 according to some example embodiments of the present inventive concepts. FIG. 5 illustrates a cross-sectional view taken along line D-D′ of FIG. 1 according to some example embodiments of the present inventive concepts.

Referring to FIGS. 1, 4, and 5, a first connection pattern CP1 may be connected to the first floating diffusion region FD1. The first connection pattern CP1 may be in contact with a top surface of the first floating diffusion region FD1. The first connection pattern CP1 may be formed of a conductive material. The source follower gate electrode SFG may have a first thickness TH1. The first connection pattern CP1 may have a second thickness TH2. The second thickness TH2 may be the same as or less than the first thickness TH1. A portion of the first connection pattern CP1 may cover a top surface of the second separation part STI.

The first connection pattern CP1 may be formed of polysilicon or monocrystalline silicon doped with the second impurity. A concentration of the second impurity doped in the first connection pattern CP1 may be greater than that of the second impurity doped in the first floating diffusion region FD1. The first floating diffusion region FD1 may be spaced apart from a sidewall of the spacer 25. Alternatively, the first floating diffusion region FD1 may overlap a portion of the spacer 25.

The first floating diffusion region FD1 may be spaced apart by a first interval DS1 from the protruding part PP2 of the transfer gate electrode TG. The first connection pattern CP1 may be spaced apart by a second interval DS2 from the protruding part PP2 of the transfer gate electrode TG. The second interval DS2 may be greater than the first interval DS1. Therefore, a transfer transistor TX may improve in gate induced drain leakage (GIDL) characteristics. Accordingly, the image sensor 100 may accomplish sharp image quality.

When viewed in plan as shown in FIG. 1, the first connection pattern CP1 may be in contact with the first floating diffusion regions FD1. The first connection pattern CP1 may have a tetragonal shape when viewed in plan. Alternatively, the first connection pattern CP1 may have an oval shape, a circular shape, or a polygonal shape when viewed in plan. Two first connection patterns CP1 may be provided on one group section LRG. The first floating diffusion regions FD1 of the first and fourth light-receiving sections LR(1) and LR(4) may be in contact with one first connection pattern CP1. The first floating diffusion regions FD1 of the second and third light-receiving sections LR(2) and LR(3) may be in contact with another one first connection pattern CP1.

The second connection pattern CP2 may connect the first connection patterns CP1 positioned on one group section LRG to the source follower gate electrode SFG. The second connection pattern CP2 may extend to connect the first connection pattern CP1 to the second floating diffusion region FD2. The second connection pattern CP2 may be in contact with a top surface and a lateral surface of the first connection pattern CP1, a top surface of the second separation part STI, a top surface of the source follower gate electrode SFG, and a top surface of the second floating diffusion region FD2. The second connection pattern CP2 may be spaced apart by a third interval DS3 from the protruding part PP2 of the transfer gate electrode TG. The third interval DS3 may be greater than the second interval DS2.

The second connection pattern CP2 may be formed of a conductive material. The second connection pattern CP2 may include metal. The metal included in the second connection pattern CP2 may have resistivity less than that of metal included in the first interconnection line IT1 which will be discussed below. The second connection pattern CP2 may include, for example, at least one selected from titanium, titanium nitride, tantalum, and/or tantalum nitride. This difference in resistivity may increase a conversion gain and reduce a parasitic capacitance between the second connection pattern CP2 and its adjacent interconnection lines. Accordingly, the image sensor 100 may accomplish sharp image quality.

Referring to FIGS. 2 to 5, the first surface 1a of the substrate 1 may be covered with a first interlayer dielectric layer IL1. A first contact plug 21 may penetrate the first interlayer dielectric layer IL1 to come into contact with the transfer gate electrode TG. A first interconnection line IT1 may be disposed on the first interlayer dielectric layer IL1. The first interconnection line IT1 may be connected to the first contact plug 21. A top end of the second connection pattern CP2 may be located at a first level LV1. A bottom surface of the first interconnection line IT1 may be located at a second level LV2. The second level LV2 may be higher than the first level LV1. This difference in level may increase a conversion gain and reduce a parasitic capacitance between the second connection pattern CP2 and its adjacent interconnection lines due to an increase in distance therebetween. Accordingly, the image sensor 100 may accomplish sharp image quality.

The top surface of the first connection pattern CP1 may be located at a third level LV3. The third level LV3 may be lower than the first level LV1.

A second contact plug 23 may penetrate the first interlayer dielectric layer IL1 to come into contact with the source/drain region SD on a side of the first reset gate electrode RG1. A second interconnection line IT2 may be disposed on the first interlayer dielectric layer IL1. The second interconnection line IT2 may be connected to the second contact plug 23. Second, third, and fourth interlayer dielectric layers IL2, IL3, and IL4 may be sequentially stacked on the first interlayer dielectric layer IL1. Third and fourth interconnection lines IT3 and IT4 of FIG. 1 may be disposed between the first to fourth interlayer dielectric layers IL1 to IL4. Each of the first, second, third, and fourth interlayer dielectric layers IL1, IL2, IL3, and IL4 may have a single-layered or multi-layered structure of at least one selected from silicon oxide, silicon nitride, silicon oxynitride, and porous dielectrics.

The second surface 1b may be provided thereunder with a fixed charge layer 40 in contact with the second surface 1b. The fixed charge layer 40 may be formed either of a metal oxide layer including oxygen whose amount is less than its stoichiometric ratio or of a metal fluoride layer including fluorine whose amount is less than its stoichiometric ratio. The fixed charge layer 40 may thus have a negative fixed charge. The fixed charge layer 40 may be formed of one of metal oxide and metal fluoride that include at least one metal selected from hafnium (Hf), zirconium (Zr), aluminum (Al), tantalum (Ta), titanium (Ti), yttrium (Y), and/or lanthanides. A hole accumulation may occur around the fixed charge layer 40. Therefore, dark current and white spot may be effectively reduced. For example, the fixed charge layer 40 may be at least one selected from an aluminum oxide layer and a hafnium oxide layer.

An antireflective layer 42 may be disposed beneath the fixed charge layer 40. The antireflective layer 42 may include, for example, silicon nitride. A light-shield pattern 44 and a low-refractive pattern 46 may be sequentially stacked on the antireflective layer 42. The light-shield pattern 44 and the low-refractive pattern 46 may have a mesh shape when viewed in plan. The light-shield pattern 44 and the low-refractive pattern 46 may overlap the first separation part DTI. Alternatively, in consideration of an incidence angle, neither the light-shield pattern 44 nor the low-refractive pattern 46 may overlap the first separation part DTI.

The light-shield pattern 44 may include a material, such as titanium, which is not transparent to light. A sidewall of the low-refractive pattern 46 may be aligned with that of the light-shield pattern 44. The light-shield pattern 44 and the low-refractive pattern 46 may prevent or reduce in likelihood crosstalk between neighboring pixels. The low-refractive pattern 46 may include an organic material. The low-refractive pattern 46 may have a refractive index less than that of color filters CF1 and CF2. For example, the low-refractive pattern 46 may have a refractive index equal to or less than about 1.3.

A first color filter CF1 and a second color filter CF2 may be disposed beneath the antireflective layer 42. Microlenses ML may be correspondingly disposed beneath the first color filter CF1 and the second color filter CF2. The first color filter CF1 may cover the first group section LRG(1). The second color filter CF2 may cover the second group section LRG(2). One microlens ML may cover one light-receiving section LR or one group section LRG. Each of the first and second color filters CF1 and CF2 may include a photoresist material to which a dye or pigment is added. The first color filter CF1 may have one of blue, red, and/or green colors, and the second color filter CF2 may have another of blue, red, and/or green colors. Alternatively, the first color filter CF1 or the second color filter CF2 may be transparent, and in this case, may be formed as a portion of the microlens ML.

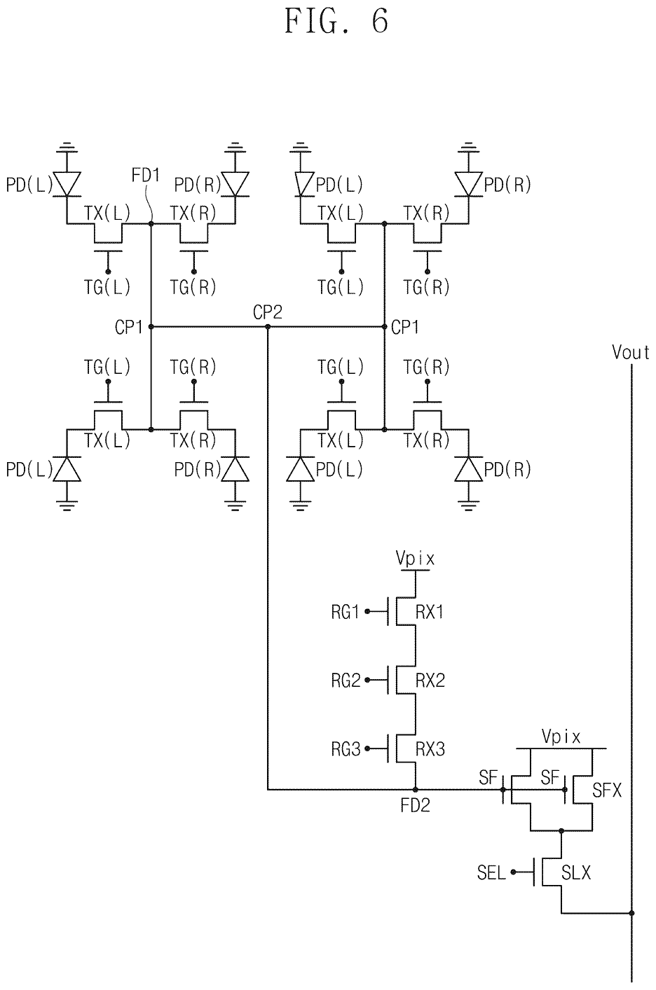

FIG. 6 illustrates a circuit diagram showing an image sensor of FIG. 1 according to some example embodiments of the present inventive concepts.

Referring to FIGS. 1 and 6, a left transparent transistor TX(L) may include a left transfer gate electrode TG(L) and a first floating diffusion region FD1 adjacent to the left transfer gate electrode TG(L). The right transfer transistor TX(R) may include a right transfer gate electrode TG(R) and a first floating diffusion region FD1 adjacent to the right transfer gate electrode® TG(R). A first reset transfer RX1 may include a first reset gate electrode RG1 and source/drain regions SD on opposite sides of the first reset gate electrode RG1. A second reset transistor RX2 may include a second reset gate electrode RG2 and source/drain regions SD on opposite sides of the second reset gate electrode RG2. A third reset transistor RX3 may include a third reset gate electrode RG3 and source/drain regions SD on opposite sides of the third reset gate electrode RG3. A source follower transistor SFX may include a source follower gate electrode SFG and source/drain regions SD on opposite sides of the source follower gate electrode SFG. A selection transistor SLX may include a selection gate electrode SEL and source/drain regions SD on opposite sides of the selection gate electrode SEL.

The source/drain region SD of the source follower transistor SFX disposed on the fourth light-receiving section LR(4) of the first group section LRG(1) may be connected through the third line IT3 to the source/drain region SD of the selection transistor SLX disposed on the first light-receiving section LR(1) of the second group section LRG(2).

The source/drain region SD of the third reset transistor RX3 disposed on the third light-receiving section LR(3) of the first group section LRG(1) may be connected through the fourth interconnection line IT4 to the source/drain region SD of the second reset transistor RX2 disposed on the second light-receiving section LR(2) of the second group section LRG(2).

Based on an operation mode of the image sensor 100, among the left transfer transistors TX(L) and the right transfer transistors TX(R) of the first to fourth light-receiving sections LR(1) to LR(4), all may be turned on sequentially, only a few may be turned on, or all may be turned on simultaneously.

The first to third reset transistors RX1 to RX3 may be connected in series to each other. The number of the first to third reset transistors RX1 to RX3 that are turned on may be changed depending on illumination at which the image sensor 100 operates. When the image sensor 100 operates at high illumination, the first to third reset transistors RX1 to RX3 may all be turned on. Therefore, the image sensor 100 may have an increased full well capacity (FWC). When the image sensor 100 operates at low illumination, only one of the first to third reset transistors RX1 to RX3 may be turned on. The second and third reset transistors RX2 and RX3 may be called a dual conversion gain transistor.

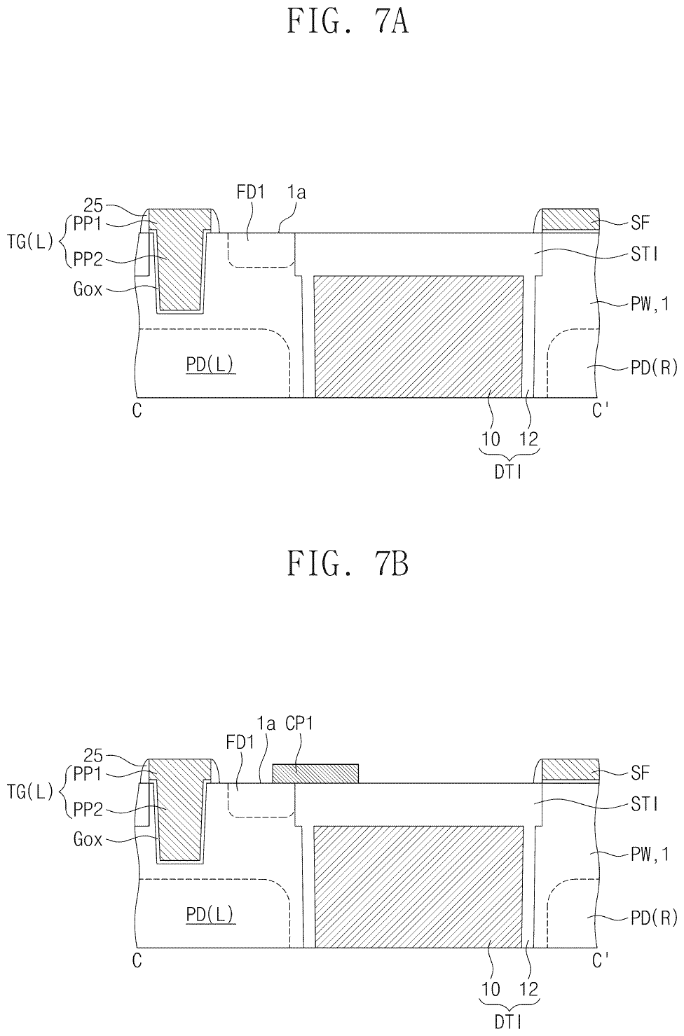

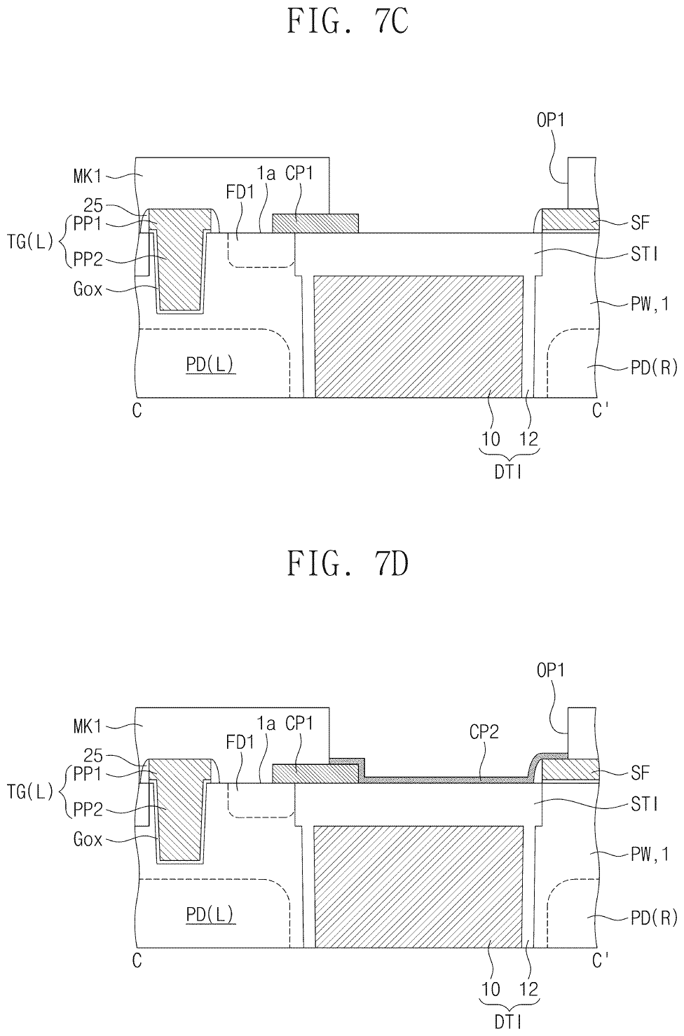

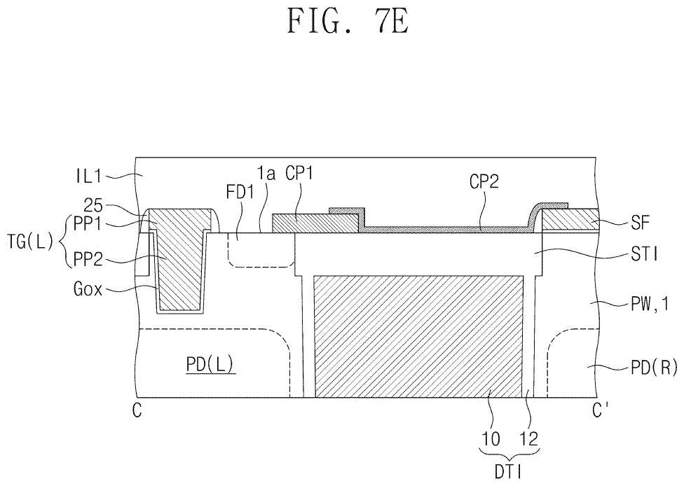

FIGS. 7A to 7E illustrate cross-sectional views showing a method of fabricating an image sensor having the cross-section of FIG. 4.

Referring to FIGS. 5 and 7A, on a substrate 1, there may be formed a first separation part DTI, a second separation part STI, a photoelectric conversion region FD, a gate dielectric layer Gox, a transfer gate electrode TG, a source follower gate electrode SFG, a first floating diffusion region FD1, and a second floating diffusion region FD2.

Referring to FIG. 7B, a first connection pattern CP1 may be formed on a first surface 1a of the substrate 1. A selective epitaxial growth (SEG) method may be performed in such a way that a silicon layer is grown to form the first connection pattern CP1. Alternatively, a silicon layer may be deposited and then patterned to form the first connection pattern CP1. During the growth or deposition of the silicon layer, a second impurity may be in-situ doped in the first connection pattern CP1. Alternatively, after the growth or deposition of the silicon layer, a second impurity may be doped in the silicon layer.

Referring to FIGS. 5 and 7C, a preliminary dielectric pattern MK1 maybe formed on the first surface 1a of the substrate 1. The preliminary dielectric pattern MK1 may have a first opening OP1. The preliminary dielectric pattern MK1 may cover the transfer gate electrode TG and the first floating diffusion region FD1. The first opening OP1 may expose a top surface and a lateral surface of the first connection pattern CP1, a top surface and a lateral surface of the source follower gate electrode SFG, a top surface and a portion of the second floating diffusion region FD2, and a top surface of the second separation part STI. The preliminary dielectric pattern MK1 may be formed of, for example, silicon oxide. Alternatively, the preliminary dielectric pattern may serve as a mask pattern. In this case, the preliminary dielectric pattern MK1 may be formed of a photoresist material or a spin on hardmask (SOH) material.

Referring to FIGS. 5 and 7D, the first opening OP1 may be used to deposit a conductive layer to form a second connection pattern CP2. The second connection pattern CP2 may include, for example, at least one selected from titanium, titanium nitride, tantalum, and/or tantalum nitride. The deposition of the conductive layer may be achieved by, for example, sputtering, physical vapor deposition (PVD), chemical vapor deposition (CVD), or atomic layer deposition (ALD). The conductive layer may also be formed on a surface of the preliminary dielectric pattern MK1, but the conductive layer on the surface of the preliminary dielectric pattern MK1 may be removed by an individual process. The second connection pattern CP2 may be formed to contact the first floating diffusion region FD1, the second floating diffusion region FD2, and the source follower gate electrode SFG.

Referring to FIG. 7E, the first opening OP1 may be filled with a dielectric material to form a first interlayer dielectric layer IL1. When the preliminary dielectric pattern MK1 is formed of silicon oxide, and when the dielectric material filling the first opening OP1 is formed of silicon oxide the same as that used for forming the preliminary dielectric pattern MK1, an interface may not be found in the first interlayer dielectric layer IL1. When the preliminary dielectric pattern MK1 is formed of a photoresist pattern or a spin on hardmask (SOH) material, the preliminary dielectric pattern MK1 may be removed. A first interlayer dielectric layer IL1 may be formed on the first surface 1a. Referring back to FIGS. 1 to 5, subsequent ordinary processes may be performed to fabricate an image sensor 100.

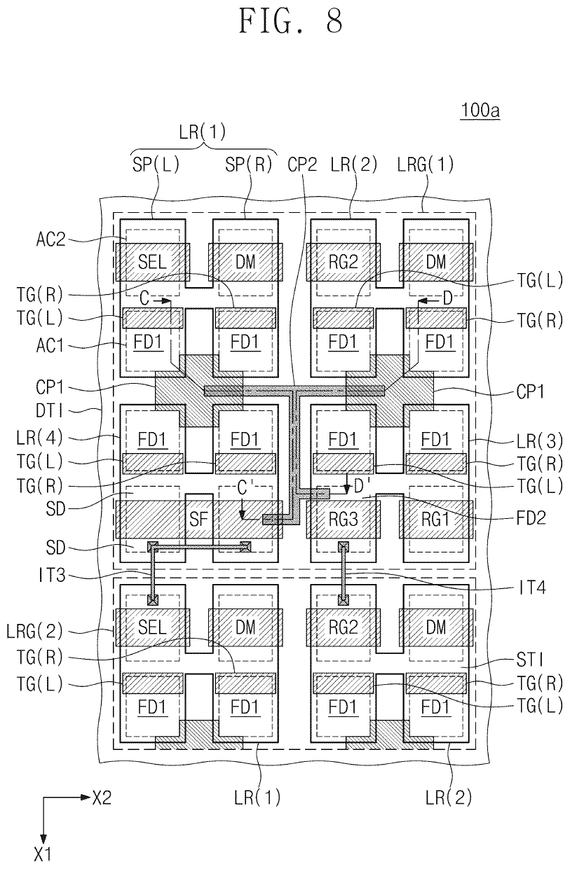

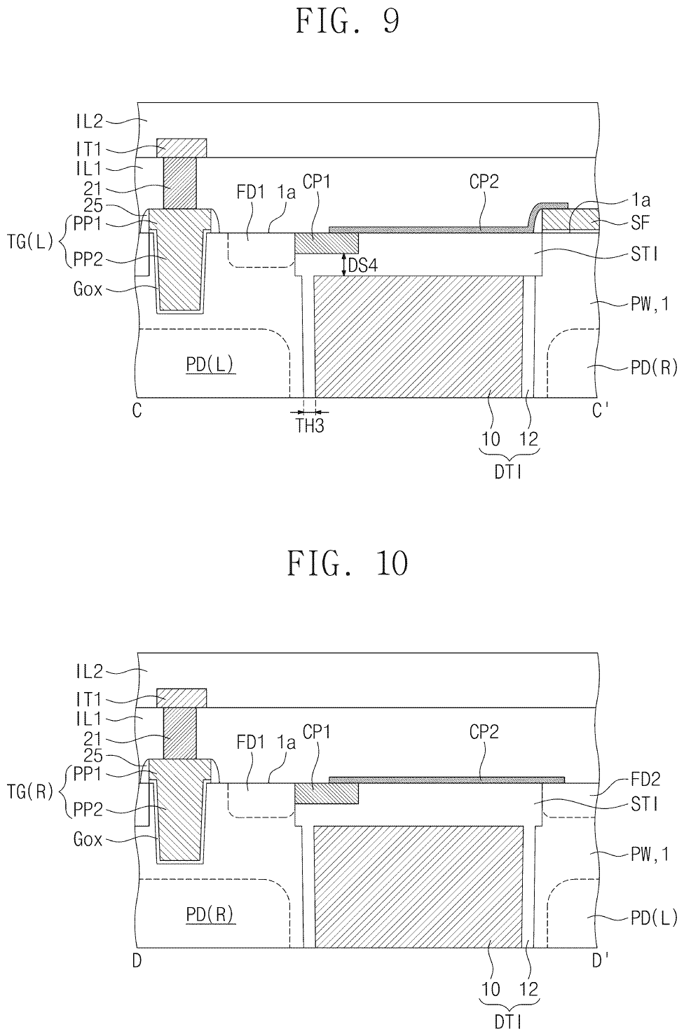

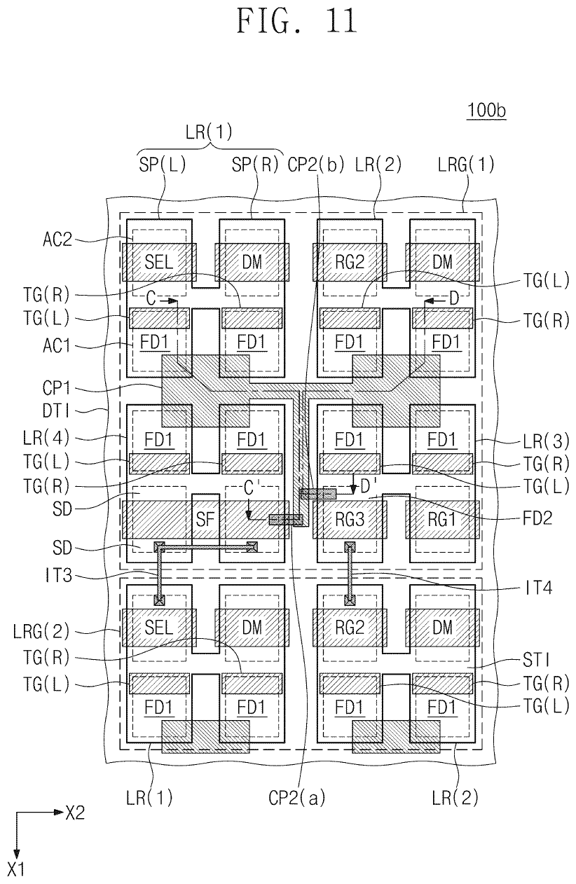

FIG. 8 illustrates a layout showing an image sensor according to some example embodiments of the present inventive concepts. FIG. 9 illustrates a cross-sectional view taken along line C-C′ of FIG. 8 according to some example embodiments of the present inventive concepts. FIG. 10 illustrates a cross-sectional view taken along line D-D′ of FIG. 8 according to some example embodiments of the present inventive concepts.

Referring to FIGS. 8 to 10, in an image sensor 100a according to some example embodiments, the first connection pattern CP1 may be disposed in the second separation part STI. The first connection pattern CP1 may have a polygonal shape with four or more when viewed in plan. The first connection pattern CP1 may be in contact with a lateral surface of the first floating diffusion region FD1 or a lateral surface of the substrate 1. A top surface of the first connection pattern CP1 may be coplanar with that (or the first surface 1a) of the substrate 1 or that of the second separation part STI. A fourth interval DS4 between the first connection pattern CP1 and the separation conductive pattern 10 of the first separation part DTI may be greater than a thickness TH3 of the separation dielectric pattern 12 of the first separation part DTI. Other configurations may be identical or similar to those discussed above.

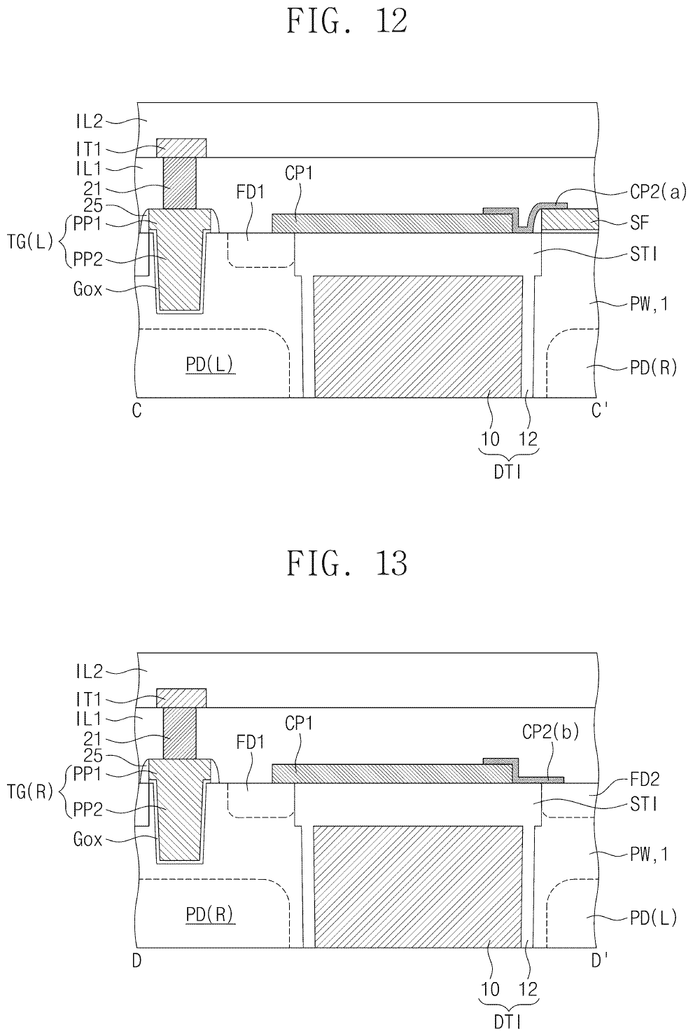

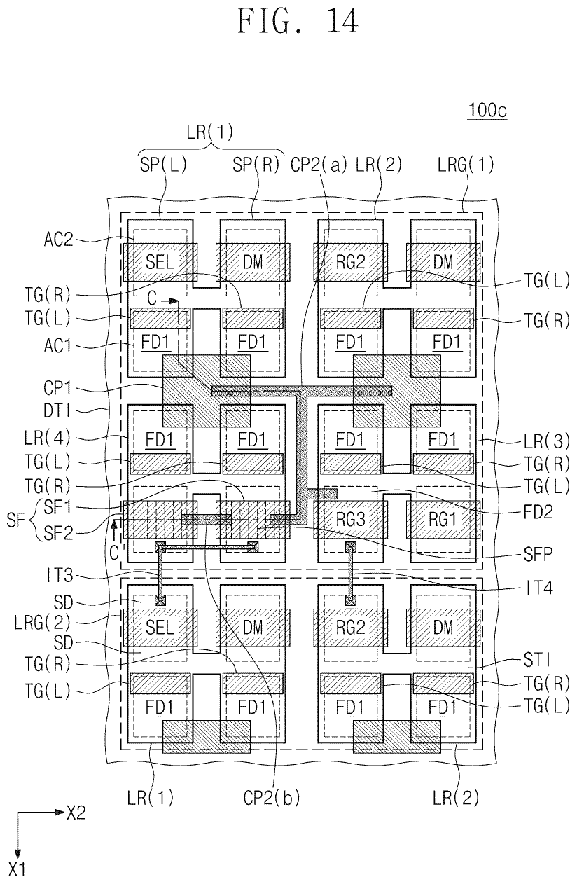

FIG. 11 illustrates a layout showing an image sensor according to some example embodiments of the present inventive concepts. FIG. 12 illustrates a cross-sectional view taken along line C-C′ of FIG. 11 according to some example embodiments of the present inventive concepts. FIG. 13 illustrates a cross-sectional view taken along line D-D′ of FIG. 11 according to some example embodiments of the present inventive concepts.

Referring to FIGS. 11 to 13, in an image sensor 100b according to some example embodiments, the first connection pattern CP1 may connect neighboring first floating diffusion regions FD1 to each other. A portion of the first connection pattern CP1 may extend between the third light-receiving section LR(3) and the fourth light-receiving section LR(4) to overlap the first separation part DTI. Two second connection patterns CP2 may be provided on one group section LRG. One pattern CP2(a) of the two second connection patterns CP2 may connect the first connection pattern CP1 to the source follower gate electrode SFG. The other pattern CP2(b) of the two second connection patterns CP2 may connect the first connection pattern CP1 to the second floating diffusion region FD2. Other configurations may be identical or similar to those discussed above.

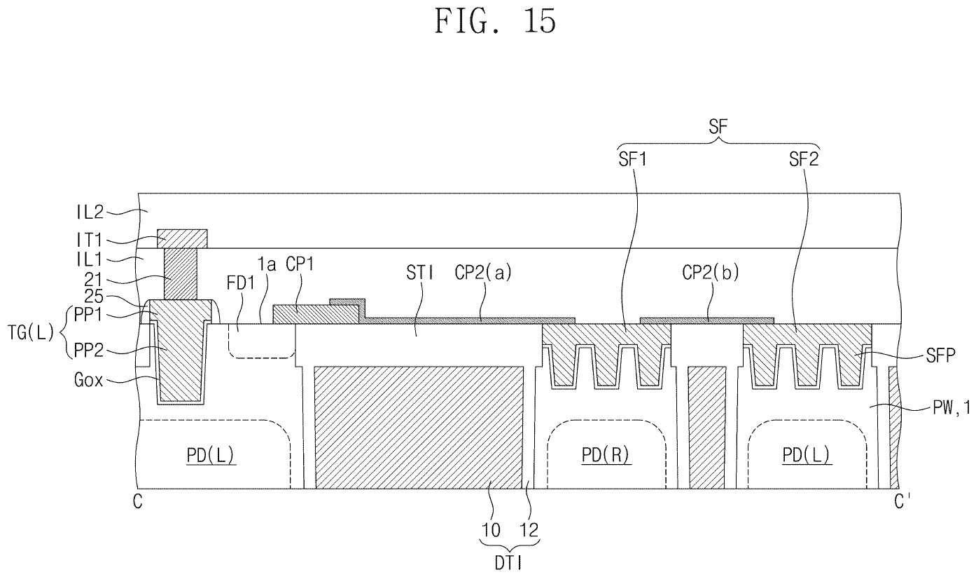

FIG. 14 illustrates a layout showing an image sensor according to some example embodiments of the present inventive concepts. FIG. 15 illustrates a cross-sectional view taken along line C-C′ of FIG. 14 according to some example embodiments of the present inventive concepts.

Referring to FIGS. 14 and 15, in an image sensor 100c according to some example embodiments, the source follower gate electrode SFG may include a first sub-source follower gate electrode SFG1 and a second sub-source follower gate electrode SFG2 that are spaced apart from each other. The first sub-source follower gate electrode SFG1 may be disposed on the right sub-section SP(R) of the fourth light-receiving section LR(4). The second sub-source follower gate electrode SFG2 may be disposed on the left sub-section SP(L) of the fourth light-receiving section LR(4). The first sub-source follower gate electrode SFG1 and the second sub-source follower gate electrode SFG2 may be buried in the substrate 1. The first sub-source follower gate electrode SFG1 and the second sub-source follower gate electrode SFG2 may have their top surfaces coplanar with that (or the first surface 1a) of the substrate 1. Each of the first sub-source follower gate electrode SFG1 and the second sub-source follower gate electrode SFG2 may include at least one protruding part SFP that protrudes from a lower portion thereof. Thus, each of the first sub-source follower gate electrode SFG1 and the second sub-source follower gate electrode SFG2 may have an uneven structure on a bottom surface thereof. Therefore, the source follower transistor SFX may have an increased amount of current and reduced noise to achieve sharp image quality.

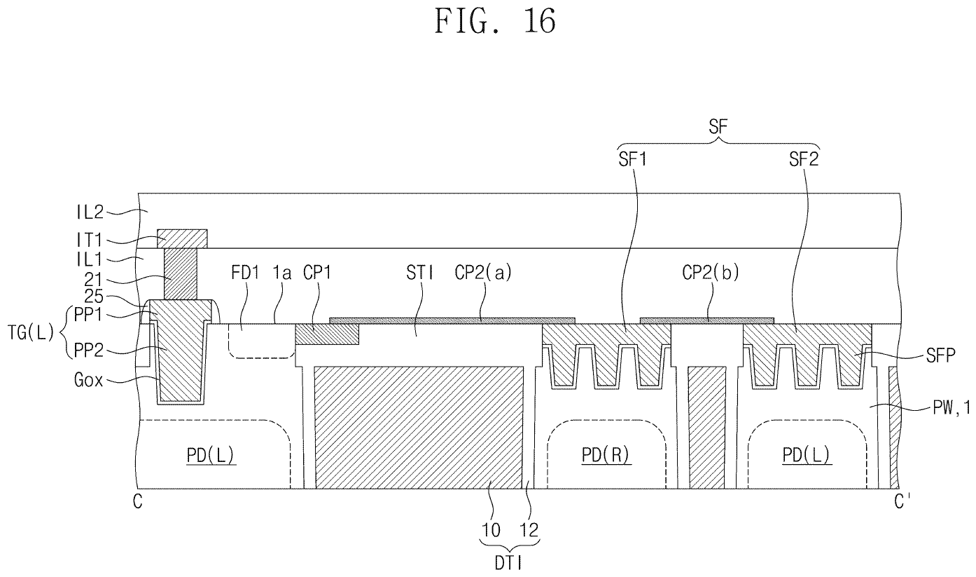

Two second connection patterns CP2 may be provided. One pattern CP2(a) of the two second connection patterns CP2 may connect the first connection pattern CP1 to the second floating diffusion region FD2 and the first sub-source follower gate electrode SFG1. The other pattern CP2(b) of the two second connection patterns CP2 may connect the first sub-source follower gate electrode SFG1 to the second sub-source follower gate electrode SFG2. As shown in the cross-section of FIG. 16, the second connection patterns CP2 may all be flat. Other configurations may be identical or similar to those discussed with reference to FIGS. 2 to 5.

FIG. 16 illustrates a cross-sectional view taken along line C-C′ of FIG. 14 according to some example embodiments of the present inventive concepts.

Referring to FIG. 16, in an image sensor according to some example embodiments, the first connection pattern CP1 may be positioned in the second separation part STI as shown in FIG. 9. Other configurations may be identical or similar to those discussed with reference to FIGS. 9, 14 and 15.

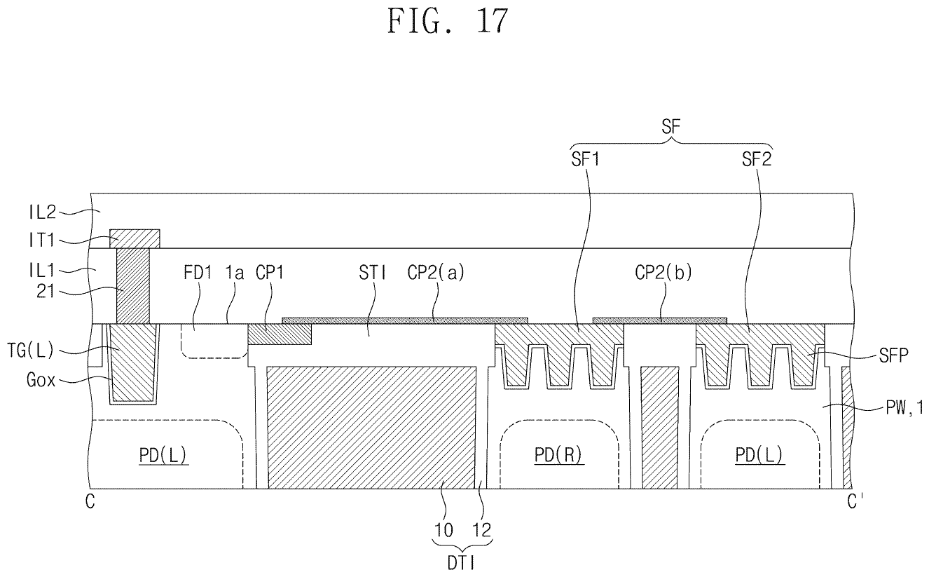

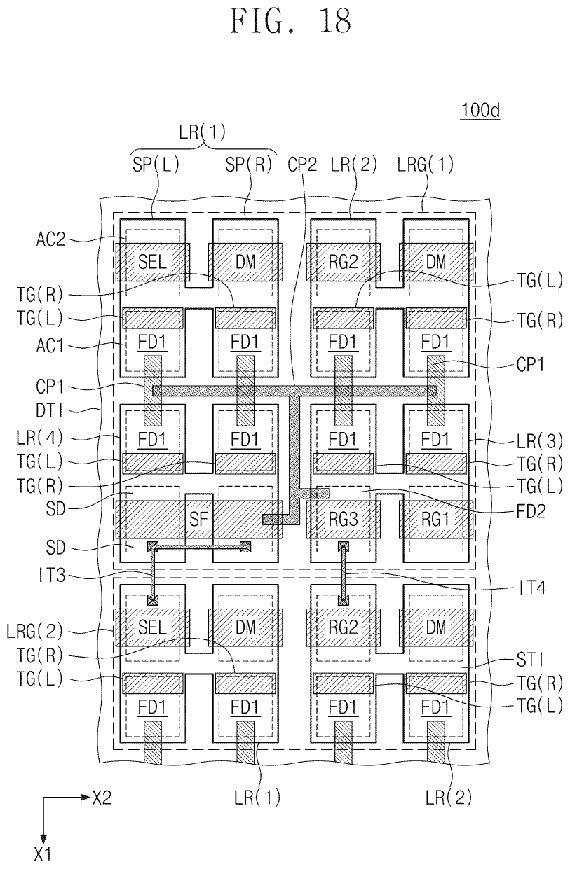

FIG. 17 illustrates a cross-sectional view taken along line C-C′ of FIG. 14 according to some example embodiments of the present inventive concepts.

Referring to FIG. 17, in an image sensor according to some example embodiments, the transfer gate electrode TG may not protrude above a top surface (or the first surface 1a) of the substrate 1. The transfer gate electrode TG may be disposed in the substrate 1. A top surface of the transfer gate electrode TG may be coplanar with that (or the first surface 1a) of the substrate 1. Other configurations may be identical or similar to those discussed with reference to FIG. 16.

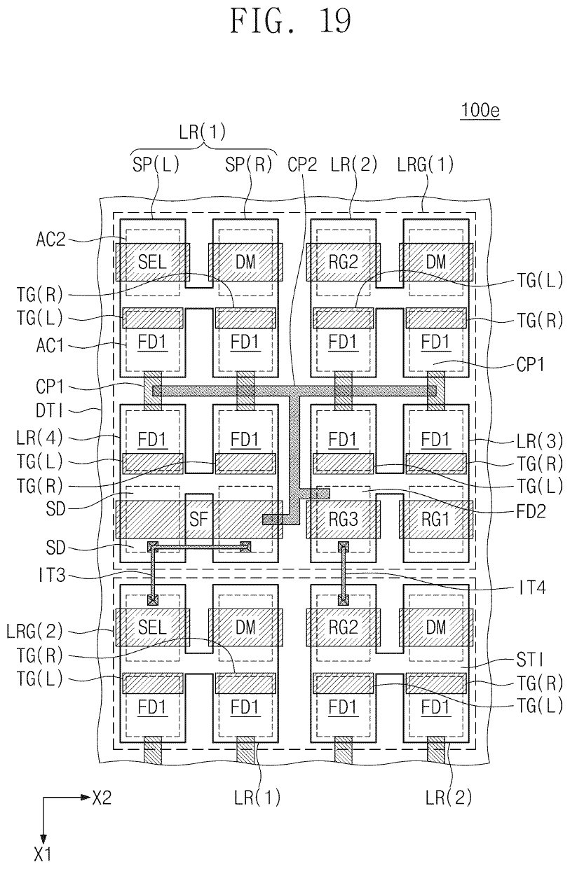

FIG. 18 illustrates a layout showing an image sensor according to some example embodiments of the present inventive concepts.

Referring to FIG. 18, in an image sensor 100d according to some example embodiments, four first connection patterns CP1 may be provided on one group section LRG. The first floating diffusion regions FD1 of the left sub-sections SP(L) of the first and fourth light-receiving sections LR(1) and LR(4) may be in contact with one first connection pattern CP1. The first floating diffusion regions FD1 of the right sub-sections SP(R) of the first and fourth light-receiving sections LR(1) and LR(4) may be in contact with another one first connection pattern CP1. The first floating diffusion regions FD1 of the left sub-sections SP(L) of the second and third light-receiving sections LR(2) and LR(3) may be in contact with another one first connection pattern CP1. The first floating diffusion regions FD1 of the right sub-sections SP(R) of the second and third light-receiving sections LR(2) and LR(3) may be in contact with another one first connection pattern CP1. The first connection patterns CP1 may be in contact with top surfaces of the first floating diffusion regions FD1 as shown in FIG. 4. The second connection pattern CP2 may connect the four first connection patterns CP1 positioned on one group section LRG to the source follower gate electrode SFG and the second floating diffusion region FD2. Other configurations may be identical or similar to those discussed with reference to FIGS. 1 to 6.

FIG. 19 illustrates a layout showing an image sensor according to some example embodiments of the present inventive concepts.

Referring to FIG. 19, in an image sensor 100e according to some example embodiments, the first connection patterns CP1 may be disposed in the second separation part STI. The first connection patterns CP1 may be in contact with lateral surfaces of the first floating diffusion regions FD1 or a lateral surface of the substrate 1. The first connection patterns CP1 may have their top surfaces coplanar with that (or the first surface 1a) of the substrate 1 or that of the second separation part STI. Other configurations may be identical or similar to those discussed with reference to FIGS. 9, 10, and 18.

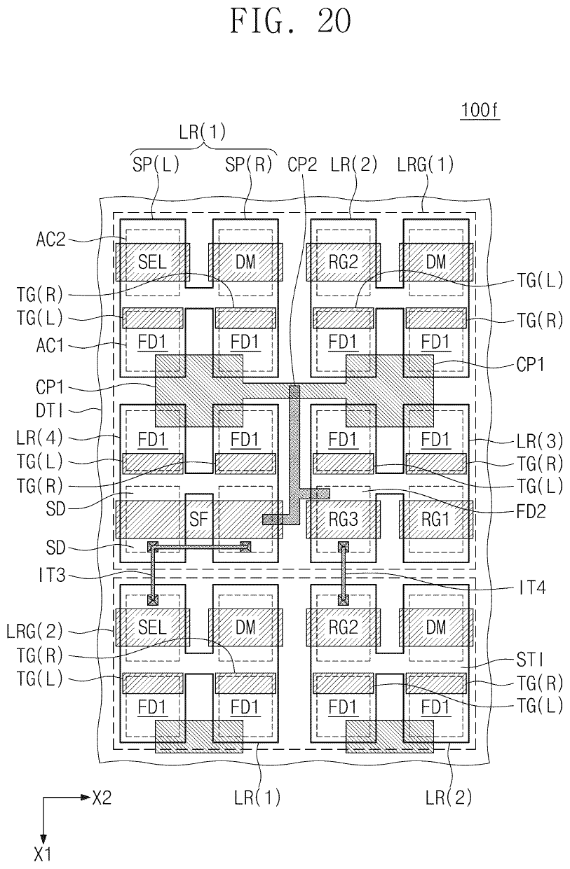

FIG. 20 illustrates a layout showing an image sensor according to some example embodiments of the present inventive concepts.

Referring to FIG. 20, in an image sensor 100f according to some example embodiments, one first connection pattern CP1 may be provided on one group section LRG. The first connection pattern CP1 may cover and connect top surfaces of the first floating diffusion regions FD1 of the first to fourth light-receiving sections LR(1) to LR(4). The first connection pattern CP1 of FIG. 20 may have a shape similar to a dumbbell when viewed in plan. The second connection pattern CP2 may extend between the third and fourth light-receiving sections LR(3) and LR(4) to come into contact with a center of the first connection pattern CP1. Other configurations may be identical or similar to those discussed with reference to FIGS. 1 to 6.

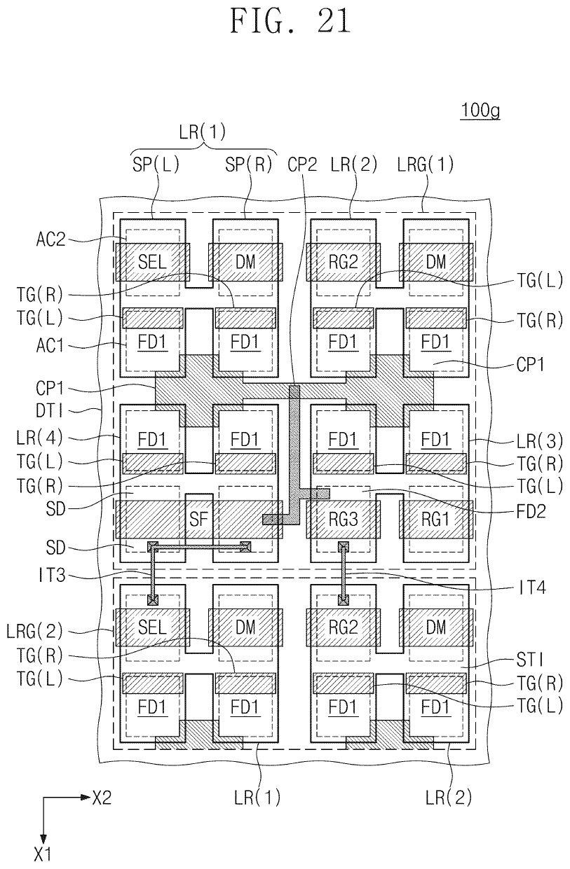

FIG. 21 illustrates a layout showing an image sensor according to some example embodiments of the present inventive concepts.

Referring to FIG. 21, in an image sensor 100g according to some example embodiments, the first connection pattern CP1 may be disposed in the second separation part STI. The first connection pattern CP1 may cover and connect lateral surfaces of the first floating diffusion regions FD1 of the first to fourth light-receiving sections LR(1) to LR(4). The first connection patterns CP1 may have their top surfaces coplanar with that of the substrate 1 or that of the second separation part STI. Other configurations may be identical or similar to those discussed with reference to FIGS. 9, 10, and 20.

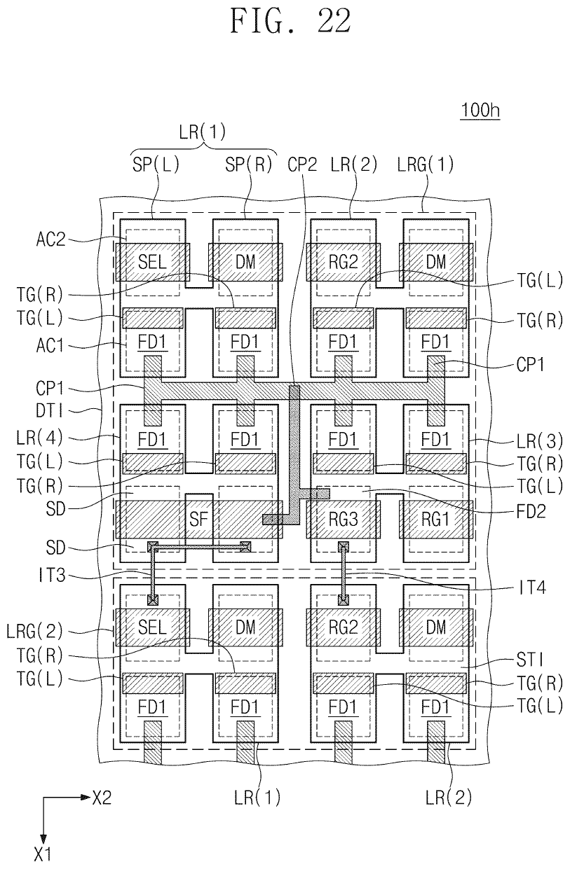

FIG. 22 illustrates a layout showing an image sensor according to some example embodiments of the present inventive concepts.

Referring to FIG. 22, in an image sensor 100h according to some example embodiments, one first connection pattern CP1 may be provided on one group section LRG. The first connection pattern CP1 may cover and connect top surfaces of the first floating diffusion regions FD1 of the first to fourth light-receiving sections LR(1) to LR(4). A planar shape of the first connection pattern CP1 may be different from that of the first connection pattern CP1 of FIG. 20. The first connection pattern CP1 of FIG. 22 may have a shape similar to a fence when viewed in plan. The second connection pattern CP2 may extend between the third and fourth light-receiving sections LR(3) and LR(4) to come into contact with a center of the first connection pattern CP1. Other configurations may be identical or similar to those discussed above with reference to FIG. 20.

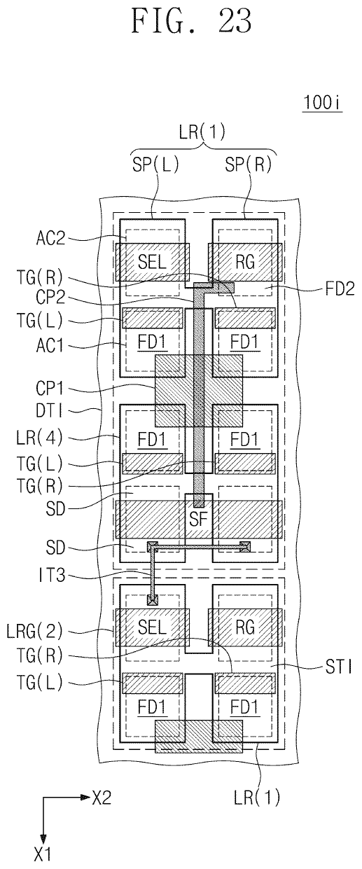

FIG. 23 illustrates a layout showing an image sensor according to some example embodiments of the present inventive concepts.

Referring to FIG. 23, in an image sensor 100i according to some example embodiments, one group section LRG may include first and second light-receiving sections LR(1) and LR(2) that are disposed side by side in the first direction X1. The transfer gate electrodes TG and the first floating diffusion regions FD1 may be disposed on the first active regions AC1 of the first and second light-receiving sections LR(1) and LR(2). The selection gate electrode SEL may be disposed on the second active region AC2 of the left sub-section SP(L) in the first light-receiving section LR(1). The reset gate electrode RG may be disposed on the second active region AC2 of the right sub-section SP(R) in the first light-receiving section LR(1). The second floating diffusion region FD2 may be disposed in the substrate 1 on a side of the reset gate electrode RG. The source follower gate electrode SFG may be disposed on the second active region AC2 of the left sub-section SP(L) in the second light-receiving section LR(2) of the first group section LRG(1). The source follower gate electrode SFG may extend to run across the second active region AC2 of the right sub-section SP(R) in the second light-receiving section LR(2) of the first group section LRG(1). The source/drain region SD of the source follower transistor SFX disposed on the second light-receiving section LR(2) of the first group section LRG(1) may be connected through the third interconnection line IT3 to the source/drain region SD of the selection transistor SLX disposed on the first light-receiving section LR(1) of the second group section LRG(2). Other configurations may be identical or similar to those discussed with reference to FIGS. 1 to 5.

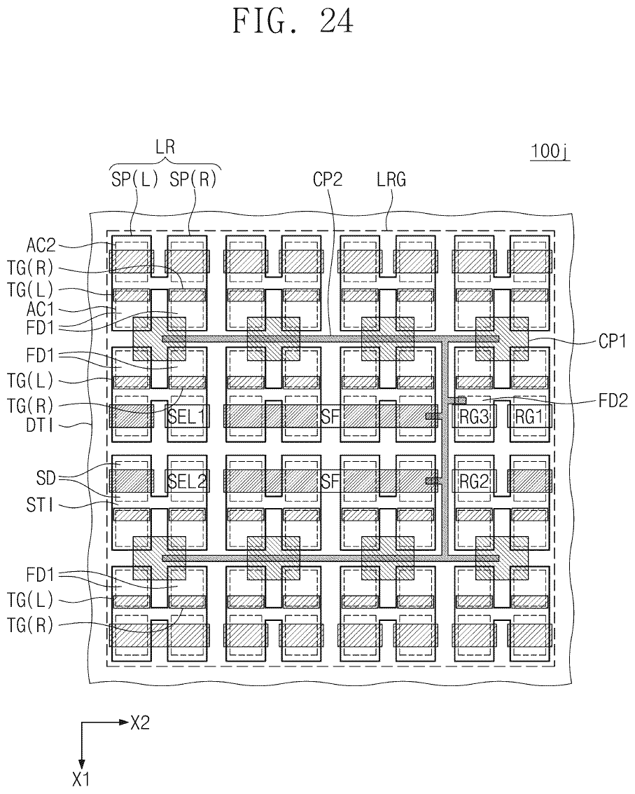

FIG. 24 illustrates a layout showing an image sensor according to some example embodiments of the present inventive concepts.

Referring to FIG. 24, in an image sensor 100j according to some example embodiments, one group section LRG may include a four-by-four array of light-receiving sections LR that are two-dimensionally arranged along the first direction X1 and the second direction X2. Eight first connection patterns CP1 may be disposed on one group section LRG. One first connection pattern CP1 may connect to each other the first floating diffusion regions FD1 of two light-receiving sections LR that are adjacent to each other along the first direction X1. Two source follower gate electrodes SFG may be provided. Each of the source follower gate electrodes SFG may be elongated along the second direction X2. The source follower gate electrodes SFG may be spaced apart from each other in the first direction X1. Each of the source follower gate electrodes SFG may run across the second active regions AC2 of two light-receiving sections LR that are disposed side by side along the second direction X2. The second connection pattern CP2 may connect the eight first connection patterns CP1 to the source follower gate electrodes SFG and the second floating diffusion region FD2. Other configurations may be identical or similar to those discussed with reference to FIGS. 1 to 5.

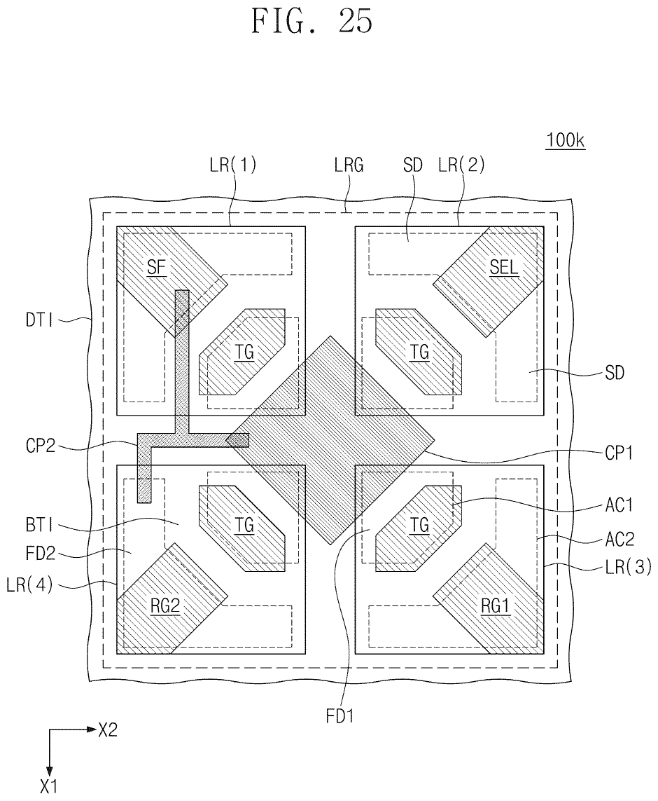

FIG. 25 illustrates a layout showing an image sensor according to some example embodiments of the present inventive concepts.

Referring to FIG. 25, in an image sensor 100k according to some example embodiments, one group section LRG may include first to fourth light-receiving sections LR(1) to LR(4) that are disposed along a clockwise direction. Each of the first to fourth light-receiving sections LR(1) to LR(4) may have a square shape. One photoelectric conversion region PD may be disposed in one light-receiving section LR.

The first active region AC1 and the second active region AC2 may be disposed on each of the first to fourth light-receiving sections LR(1) to LR(4). The first active regions AC1 may be disposed adjacent to a center of the group section LRG. The second active regions AC2 may be disposed adjacent to an outer edge of the group section LRG. The transfer gate electrode TG and the first floating diffusion region FD1 may be disposed on each of the first active regions AC1. The first connection pattern CP1 may cover all of four first floating diffusion regions FD1 that are adjacent to each other. The first connection pattern CP1 may have a rhombic shape when viewed in plan.

The source follower gate electrode SFG may be disposed on the second active region AC2 of the first light-receiving section LR(1). The selection gate electrode SEL may be disposed on the second active region AC2 of the second light-receiving section LR(2). The first reset gate electrode RG1 may be disposed on the second active region AC2 of the third light-receiving section LR(3). The second reset gate electrode RG2 may be disposed on the second active region AC2 of the fourth light-receiving section LR(4). The second reset gate electrode RG2 may be called a dual conversion gain gate electrode. The source/drain region SD on one side of the second reset gate electrode RG2 may be the second floating diffusion region FD2. The second connection pattern CP2 may connect the first connection pattern CP1 to the source follower gate electrode SFG and the second floating diffusion region FD2. Other configurations may be identical or similar to those discussed with reference to FIGS. 1 to 6.

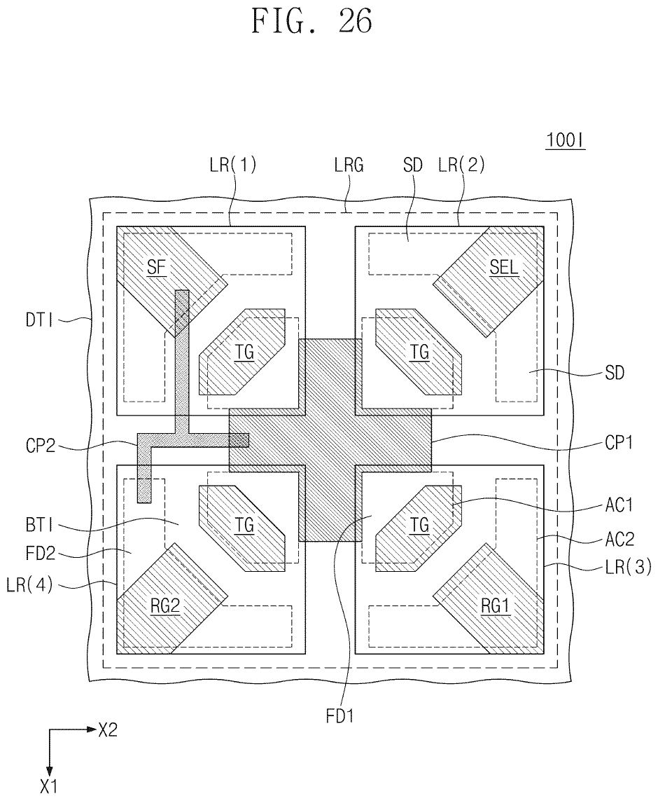

FIG. 26 illustrates a layout showing an image sensor according to some example embodiments of the present inventive concepts.

Referring to FIG. 26, an image sensor 1001 according to some example embodiments may have a layout similar to that of the image sensor 100k depicted in FIG. 25, but the first connection pattern CP1 may have a planar shape different from that of the first connection pattern CP1 depicted in FIG. 25. The first connection pattern CP1 may have a cross shape when viewed in plan. The first connection pattern CP1 may be disposed in the second separation part STI. The first connection pattern CP1 may contact and connect lateral surfaces of the first floating diffusion regions FD1 of the first to fourth light-receiving sections LR(1) to LR(4). The first connection patterns CP1 may have their top surfaces coplanar with that (or the first surface 1a) of the substrate 1 or that of the second separation part STI. Other configurations may be identical or similar to those discussed above with reference to FIG. 25.

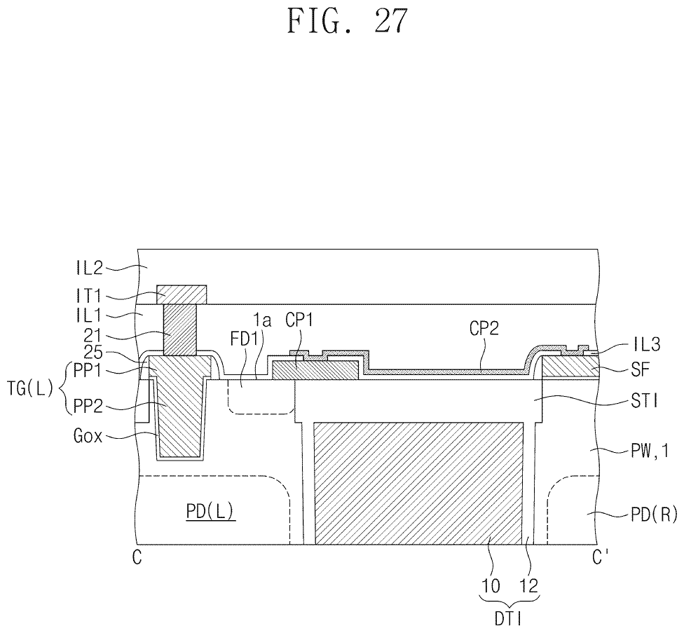

FIG. 27 illustrates a cross-sectional view showing an image sensor according to some example embodiments of the present inventive concepts.

Referring to FIG. 27, an image sensor according to some example embodiments may further include a third interlayer dielectric layer IL3 between the first connection pattern CP1 and the second connection pattern CP2 and between the source follower gate electrode SFG and the second connection pattern CP2. The second connection pattern CP2 may penetrate the third interlayer dielectric layer IL3 to come into contact with the first connection pattern CP1 and the source follower gate electrode SFG. The third interlayer dielectric layer IL3 may extend to intervene between the transfer gate electrode TG and the first interlayer dielectric layer IL1, between the first floating diffusion region FD1 and the first interlayer dielectric layer IL1, and between the second separation part STI and the second connection pattern CP2. The third interlayer dielectric layer IL3 may extend to intervene between the second floating diffusion region FD2 and the first interlayer dielectric layer IL1. The second connection pattern CP2 may penetrate the third interlayer dielectric layer IL3 to come into contact with the second floating diffusion region FD2. The third interlayer dielectric layer IL3 may be formed to have a single-layered or multi-layered structure of at least one selected from silicon oxide, silicon nitride, and silicon oxynitride. Other configurations may be identical or similar to those discussed with reference to FIGS. 4 and 5. The third interlayer dielectric layer IL3 may prevent or reduce in likelihood the second connection pattern CP2 from undesirable shorts or bridges with other components.

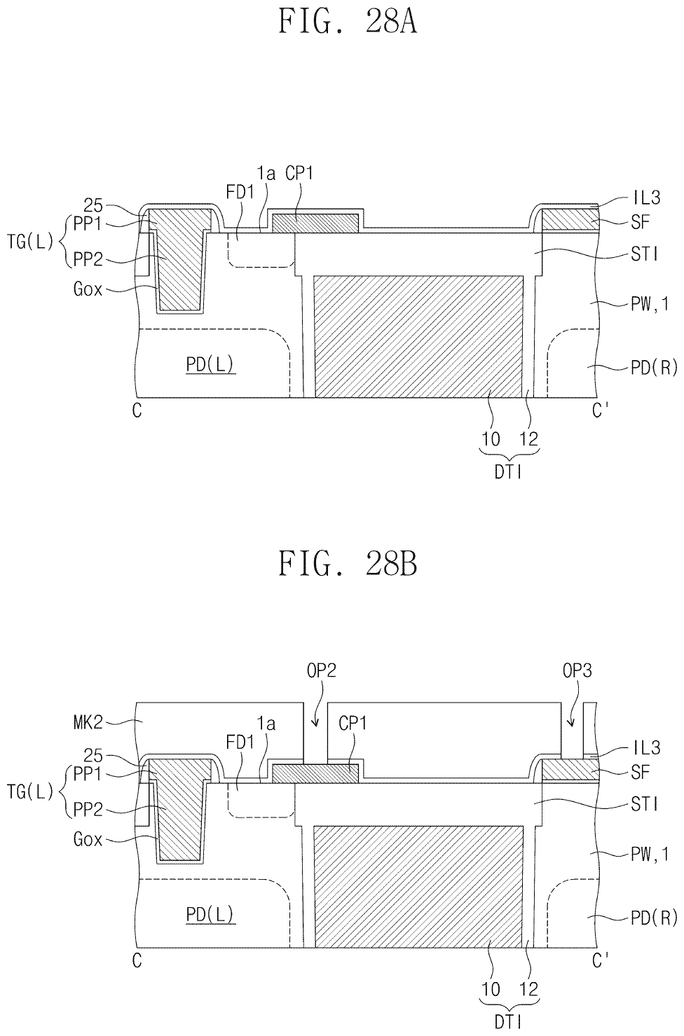

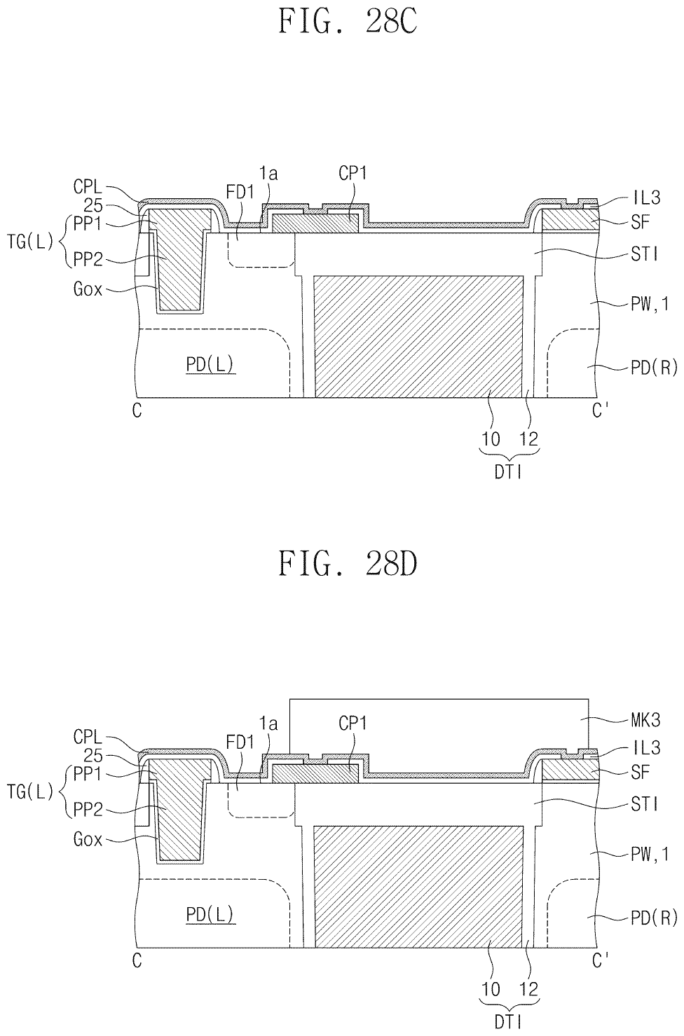

FIGS. 28A to 28D illustrate cross-sectional views showing a method of fabricating an image sensor having the cross-section of FIG. 27.

Referring to FIG. 28A, in the step of FIG. 7B, a third interlayer dielectric layer IL3 may be formed on the first surface 1a of the substrate 1. The third interlayer dielectric layer IL3 may be conformally formed. The third interlayer dielectric layer IL3 may cover the first connection pattern CP1 and the source follower gate electrode SFG.

Referring to FIG. 28B, a second mask pattern MK2 may be formed on the third interlayer dielectric layer IL3. The second mask pattern MK2 may have a second opening OP2 that overlaps the first connection pattern CP1 and a third opening OP3 that overlaps the source follower gate electrode SFG. The second mask pattern MK2 may be formed of a material having an etch selectivity with respect to the third interlayer dielectric layer IL3. The second mask pattern MK2 may be used as an etching mask to etch the third interlayer dielectric layer IL3 to partially expose top surfaces of the first connection pattern CP1 and the source follower gate electrode SFG. In this stage, a top surface of the second floating diffusion region FD2 may also be exposed.

Referring to FIG. 28C, the second mask pattern MK2 may be removed. A conductive layer CPL may be stacked on the third interlayer dielectric layer IL3. The conductive layer CPL may penetrate the third interlayer dielectric layer IL3 to come into contact with top surfaces of the first connection pattern CP1 and the source follower gate electrode SFG. In addition, the conductive layer CPL may penetrate the third interlayer dielectric layer IL3 to come into contact with a top surface of the second floating diffusion region FD2.

Referring to FIG. 28D, a third mask pattern MK3 may be formed on the conductive layer CPL. The third mask pattern MK3 may overlap a portion of the first connection pattern CP1, a portion of the source follower gate electrode SFG, and a top surface of the second separation part STI. The third mask pattern MK3 may overlap the top surface of the second floating diffusion region FD2. The third mask pattern MK3 may overlap none of the transfer gate electrode TG and the first floating diffusion region FD1. Referring back to FIG. 27, the third mask pattern MK3 may be used as an etching mask to etch the conductive layer CPL to form a second connection pattern CP2. Other process steps may be identical or similar to those discussed above.

An image sensor according to some example embodiments of the present inventive concepts may include a first connection pattern connected to a first floating diffusion region, and thus a transfer transistor may improve in gate induced drain leakage (GIDL) characteristics. In addition, the image sensor according to the present inventive concepts may further include a second connection pattern that connects the first connection pattern to a source follower gate electrode and a second floating diffusion region, and thus a parasitic capacitance may be reduced between the second connection pattern and its surrounding interconnection lines. Accordingly, the image sensor may accomplish sharp image quality.

Although the present inventive concepts have been described in connection with some example embodiments illustrated in the accompanying drawings, it will be understood to those skilled in the art that various changes and modifications may be made without departing from the technical spirit and essential feature of the present inventive concepts. It will be apparent to those skilled in the art that various substitution, modifications, and changes may be thereto without departing from the scope and spirit of the present inventive concepts. The embodiments of FIGS. 1 to 27 may be combined with each other.

What is claimed is:

1. An image sensor, comprising:
a substrate including a first light-receiving section and a second light-receiving section that are spaced apart from each other;
a first transfer gate electrode on the first light-receiving section;
a first floating diffusion region in the substrate, the first floating diffusion region on a side of the first transfer gate electrode;
a first source follower gate electrode on the second light-receiving section;
a first connection pattern connected to the first floating diffusion region;
a second connection pattern connecting the first connection pattern to the first source follower gate electrode;
a first interlayer dielectric layer covering the substrate, the first transfer gate electrode, the first source follower gate electrode, the first connection pattern, and the second connection pattern; and
a first interconnection line on the first interlayer dielectric layer, the first interconnection line connected to the first transfer gate electrode,
wherein a top end of the second connection pattern is at a first level, and
where a bottom end of the first interconnection line is at a second level higher than the first level.

2. The image sensor of claim 1, wherein
the first transfer gate electrode includes a protruding part extending into the substrate, and
a first distance between the first connection pattern and the protruding part of the first transfer gate electrode is greater than a second distance between the first floating diffusion region and the protruding part of the first transfer gate electrode.

3. The image sensor of claim 1, further comprising:
a separation part between the first light-receiving section and the second light-receiving section,
wherein the first connection pattern is on the separation part,
a top surface of the first connection pattern is at a level higher than a level of a top surface of the substrate, and
the second connection pattern covers at least a portion of a lateral surface of the first connection pattern and at least a portion of a top surface of the first source follower gate electrode.

4. The image sensor of claim 1, wherein
the first connection pattern is in contact with the first floating diffusion region, and
the second connection pattern is in contact with both the first connection pattern and the first source follower gate electrode.

5. The image sensor of claim 1, further comprising:
a separation part between the first light-receiving section and the second light-receiving section,
wherein at least a portion of the first connection pattern is in the separation part,
a top surface of the first connection pattern is coplanar with a top surface of the separation part, and
the second connection pattern covers a top surface of the first connection pattern, a lateral surface of the separation part, and a top surface of the first source follower gate electrode.

6. The image sensor of claim 5, further comprising:
a separation conductive pattern beneath the separation part; and
a separation dielectric pattern between the separation conductive pattern and the substrate,
wherein the separation dielectric pattern has a first thickness,
the first connection pattern is spaced apart by a first interval from the separation conductive pattern, and
the first interval is greater than the first thickness.

7. The image sensor of claim 1, wherein
the substrate further includes a third light-receiving section spaced apart from the first and second light-receiving sections,
the image sensor further includes a second floating diffusion region on the third light-receiving section, and
the second connection pattern contacts the second floating diffusion region.

8. The image sensor of claim 7, further comprising:
a second transfer gate electrode, a reset gate electrode, or a dual conversion gain gate electrode on a side of the second floating diffusion region.

9. The image sensor of claim 1, wherein
at least a portion of the first transfer gate electrode extends into the substrate, and
at least a portion of the first source follower gate electrode extends into the substrate.

10. The image sensor of claim 1, wherein
the substrate further includes a third light-receiving section spaced apart from the first and second light-receiving sections,
the image sensor further includes,
a second source follower gate electrode on the third light-receiving section; and
a third connection pattern connecting the first source follower gate electrode to the second source follower gate electrode, and
the third connection pattern has a thickness the same as a thickness of the second connection pattern.

11. The image sensor of claim 1, wherein
the first interconnection line includes a first metal,
the second connection pattern includes a second metal, and
a resistivity of the second metal is greater than a resistivity of the first metal.

12. The image sensor of claim 1, wherein the first connection pattern is in contact with a lateral surface of the first floating diffusion region.

13. The image sensor of claim 1, wherein an impurity concentration of the first connection pattern is greater than an impurity concentration of the first floating diffusion region.

14. The image sensor of claim 1, wherein
a top end of the first connection pattern is at a third level, and
the third level is lower than the first level.

15. The image sensor of claim 1, further comprising:
a second interlayer dielectric layer between the first source follower gate electrode and the second connection pattern, the second interlayer dielectric layer between the first connection pattern and the second connection pattern,
wherein the second connection pattern penetrates the second interlayer dielectric layer, the second connection pattern contacting the first source follower gate electrode and the first connection pattern.

16. An image sensor, comprising:
a substrate including a first light-receiving section and a second light-receiving section that are spaced apart from each other;
a first transfer gate electrode on the first light-receiving section;
a first floating diffusion region in the substrate on a side of the first transfer gate electrode;
a dual conversion gain gate electrode on the second light-receiving section;
a second floating diffusion region in the substrate on a side of the dual conversion gain gate electrode;
a first connection pattern connected to the first floating diffusion region; and
a second connection pattern connecting the first connection pattern to the second floating diffusion region,
wherein the first floating diffusion region and the first connection pattern are doped with a first impurity of a first conductivity type, and
wherein a concentration of the first impurity in the first connection pattern is greater than a concentration of the first impurity in the first floating diffusion region.

17. The image sensor of claim 16, wherein
the substrate further includes a third light-receiving section spaced apart from the first light-receiving section and the second light-receiving section,
the image sensor further includes a first source follower gate electrode on the third light-receiving section, and
the second connection pattern contacts the first source follower gate electrode.

18. The image sensor of claim 16, wherein
the first connection pattern is in contact with the first floating diffusion region, and
the second connection pattern is in contact with both the first connection pattern and the second floating diffusion region.

19. An image sensor, comprising:
a substrate including first, second, third, and fourth light-receiving sections that are arranged in a clockwise direction, each of the first to fourth light-receiving sections includes a left sub-section and a right sub-section, and the substrate has a first surface and a second surface that are opposite to each other;
a plurality of transfer gate electrodes on the left sub-sections and the right sub-sections of the first to fourth light-receiving sections;
a plurality of first floating diffusion regions on sides of the transfer gate electrodes and on the left sub-sections and the right sub-sections;
a source follower gate electrode on the fourth light-receiving section;
a second floating diffusion region on the left sub-section of the third light-receiving section;
a first connection pattern in contact with the first floating diffusion regions on the first and fourth light-receiving sections;
a second connection pattern in contact with the first floating diffusion regions on the second and third light-receiving sections;
a third connection pattern on the first surface, the third connection pattern connecting the first connection pattern, the second connection pattern, the source follower gate electrode, and the second floating diffusion region;
a color filter on the second surface; and
a microlens on the color filter,
wherein the transfer gate electrode includes a protruding part extending into the substrate, and
wherein, on the first light-receiving section, a first distance between the first connection pattern and the protruding part of the transfer gate electrode is greater than a second distance between the first floating diffusion region and the protruding part of the transfer gate electrode.

20. The image sensor of claim 19, wherein
the first floating diffusion regions, the first connection pattern, and the second connection pattern are doped with first impurities of a first conductivity type, and
a concentration of the first impurities in each of the first connection pattern and the second connection pattern is greater than a concentration of the first impurities in the first floating diffusion regions.
